(19) United States
(12) Patent Application Publication
(10) Pub. No.: US 2026/0262292 A1
(43) Pub. Date: Sep. 3, 2026

(54) DISPLAY SUBSTRATE AND DISPLAY DEVICE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Zhiqiang Yu, Beijing (CN); Dawei Feng, Beijing (CN); Xiaojuan Wu, Beijing (CN); Jiaxing Wang, Beijing (CN); Feng Liu, Beijing (CN); Jinshuai Duan, Beijing (CN); Ning Wang, Beijing (CN); Danxing Hou, Beijing (CN); Cuiyu Chen, Beijing (CN); Xiaofeng Yin, Beijing (CN)

(21) Appl. No.: 18/994,536

(22) PCT Filed: Feb. 1, 2024
(86) PCT No.: PCT/CN2024/075231

§ 371 Date: Jan. 14, 2025

(30) Foreign Application Priority Data
Sep. 15, 2023 (WO) PCT/CN2023/119009

(51) Int. Cl. H10D 86/40; G06F 3/041; G06F 3/046; H10D 86/60

(52) U.S. Cl. CPC H10D 86/441; G06F 3/0412; G06F 3/046; H10D 86/60

(57) ABSTRACT

Provided are a display substrate and a display device. In the display substrate, M first touch line groups are arranged in a second direction, and the N second touch line groups are arranged in a first direction; a first touch line group includes first touch lines connected in parallel, and a second touch line group includes second touch lines connected in parallel, the first touch lines are located in a first conductive layer, and the second touch lines are located in a second conductive layer. In an outermost one of the M first touch line groups, some first touch lines are located in a display region, and the others are located in a side region. The first touch lines are arranged in the same layer as and spaced apart from, or arranged in a different layer from a part of a third common signal line in the side region.

### CROSS REFERENCE TO RELATED APPLICATION(S)

This application is a Section 371 National Stage Application of International Application No. PCT/CN2024/075231 filed on Feb. 1, 2024, which in turn claims priority to PCT Application No. PCT/CN2023/119009 filed on Sep. 15, 2023, which are incorporated herein by reference in their entirety.

### TECHNICAL FIELD

The present disclosure relates to the field of display technology, and in particular, to a display substrate and a display device.

### BACKGROUND

With the development of remote work and distance education, the market demand for conference tablets or education tablets that integrate writing, display, collaboration and other functions are continuously increasing. At present, the electromagnetic touch technology (EMR technology) may be used in products applied in these business and distance education scenarios for writing experience.

Compared with the traditional capacitive touch technology, the electromagnetic touch technology has higher positioning accuracy, and it is possible to achieve a high-precision handwriting control and multi-level pressure sensitivity by matching with an active pen or a passive pen. However, an external touch coil is used in the current electromagnetic touch technology which generally occupies additional space, so that it is difficult to achieve a thin thickness in case a module thickness is large.

### SUMMARY

In view of the above problems, a display substrate and a display device are provided.

According to a first aspect of the present disclosure, a display substrate is provided, including a display region and a peripheral region at least partially surrounding the display region, the peripheral region includes a binding region and a binding opposite region opposite to each other in a first direction and two side regions opposite to each other in a second direction intersecting with the first direction, and the display substrate further includes: a base substrate; a second transparent electrode layer provided on the base substrate; a first conductive layer and a second conductive layer provided on the base substrate, the first conductive layer and the second conductive layer are located between the base substrate and the second transparent electrode layer; a sub-pixel provided on the base substrate and located in the display region, the sub-pixel includes a second electrode in the second transparent electrode layer; a third common signal line provided on the base substrate and located in the peripheral region; M first touch line groups and N second touch line groups provided on the base substrate, the M first touch line groups are arranged in the second direction, the N second touch line groups are arranged in the first direction, each of the M first touch line groups includes at least one first touch line, the first touch lines in one and same first touch line group are connected in parallel, each of the N second touch line groups includes at least one second touch line, the second touch lines in one and same second touch line group are connected in parallel, the first touch lines are located in the first conductive layer, the second touch lines are located in the second conductive layer, and the first touch lines are insulated and spaced apart from the second touch lines. In an outermost first touch line group among the M first touch line groups, a part of the first touch lines is located in the display region, the other part of the first touch lines is located in the side region, and the first touch lines and the third common signal line are arranged such that: the first touch lines and a part of the third common signal line in the side region are arranged in the same layer and spaced apart from each other, or the first touch lines and the part of the third common signal line in the side region are arranged in different layers, where M and N are positive integers.

According to the embodiments of the present disclosure, the first touch lines and the part of the third common signal line in the side region are arranged in the same layer; an orthographic projection of the part of the third common signal line in the side region on the base substrate defines a first pattern; and in the outermost first touch line group among the M first touch line groups, an orthographic projection of the first touch lines in the display region on the base substrate defines a second pattern, an orthographic projection of the first touch lines in the side region on the base substrate defines a third pattern, and the first pattern is located between the second pattern and the third pattern.

According to the embodiments of the present disclosure, in the outermost first touch line group among the M first touch line groups, the first touch lines in the display region have a first wire distance, the first touch lines in the side region have a second wire distance, and the first wire distance is greater than or equal to the second wire distance.

According to the embodiments of the present disclosure, the first touch lines in the first touch line groups other than the outermost first touch line group among the M first touch line groups have a third wire distance, and the third wire distance is equal to the first wire distance.

According to the embodiments of the present disclosure, in the M first touch line groups, the outermost first touch line group has a same resistance as other first touch line groups.

According to the embodiments of the present disclosure, the first touch lines and the part of the third common signal line in the side region are arranged in different layers; an orthographic projection of the third common signal line on the base substrate defines a first pattern; and in the outermost first touch line group among the M first touch line groups, an orthographic projection of the first touch lines in the display region on the base substrate defines a second pattern, an orthographic projection of the first touch lines in the side region on the base substrate defines a fourth pattern, and the first pattern overlaps with the fourth pattern.

According to the embodiments of the present disclosure, the two side regions include a first side region and a second side region, the display substrate further includes a first common signal line, a second common signal line and a touch binding end provided on the base substrate, the first common signal line and the second common signal line are located in the peripheral region, and the touch binding end is located in the binding region; the first common signal line and the second common signal line are insulated and spaced apart from each other, and the first common signal line and the second common signal line are respectively connected to the touch binding end; in the binding opposite region, an orthographic projection of the first common signal line on the base substrate is located on a side of an orthographic projection of the second common signal line on the base substrate close to an orthographic projection of the display region on the base substrate; in the side region, the orthographic projection of the second common signal line on the base substrate is located on a side of the orthographic projection of the first common signal line on the base substrate close to the orthographic projection of the display region on the base substrate; and the first touch line group is connected to the first common signal line in the binding opposite region, and the second touch line group is connected to the second common signal line in the first side region.

According to the embodiments of the present disclosure, the peripheral region further includes a plurality of corner regions, and at least one of the corner regions is located between the binding opposite region and the side region; in at least one corner region, the first common signal line includes a first extension portion, a second extension portion and a first connecting portion connected between the first extension portion and the second extension portion, and the second common signal line includes a third extension portion, a fourth extension portion and a second connecting portion connected between the third extension portion and the fourth extension portion; and the first extension portion and the third extension portion extend in the second direction and are arranged in the same layer, the second extension portion and the fourth extension portion extend in the first direction and are arranged in the same layer, the first connecting portion is located in the second transparent electrode layer, and the first connecting portion extends in the second direction and spans over the fourth extension portion.

According to the embodiments of the present disclosure, the display substrate further includes a data line provided on the base substrate, the second common signal line includes a first sub-line segment in the first side edge region, the first sub-line segment and the data line are arranged in the same layer, and the second touch line and the data line are arranged in different layers; an orthographic projection of a part of the second touch line group in the first side region on the base substrate overlaps with an orthographic projection of the first sub-line segment on the base substrate, and the second touch line group is connected to the first sub-line segment through a second transfer structure in an overlapping region of the part of the second touch line group and the first sub-line segment; and the second transfer structure is located in the second transparent electrode layer, second transfer structures connected to different second touch line groups are spaced apart from each other, or the second transfer structures connected to different second touch line groups are formed into an integrated structure.

According to the embodiments of the present disclosure, the display substrate further includes a data line provided on the base substrate, the second common signal line includes a first sub-line segment in the first side region, the first sub-line segment and the data line are arranged in the same layer, and the second touch line and the data line are arranged in different layers; and an orthographic projection of a part of the second touch line group in the first side region on the base substrate does not overlap with an orthographic projection of the first sub-line segment on the base substrate, and a plurality of second touch line groups are connected to the first sub-line segment through one and same third transfer structure.

According to the embodiments of the present disclosure, a distance between the second touch line group and the second common signal line in the second direction is less than or equal to 3500 μm.

According to the embodiments of the present disclosure, the display substrate further includes: a data line and a gate line provided on the base substrate; a shift register unit provided on the base substrate and located in the side region, an orthographic projection of the shift register unit on the base substrate is located on a side of the orthographic projection of the second common signal line on the base substrate away from the orthographic projection of the display region on the base substrate; and a first signal line provided on the base substrate and connected to the shift register unit, the first signal line is arranged in the same layer as at least one of the data line and the gate line, and an orthographic projection of the first signal line on the base substrate is located on a side of the orthographic projection of the shift register unit on the base substrate away from the orthographic projection of the second common signal line on the base substrate.

According to the embodiments of the present disclosure, the display substrate further includes: a data line and a gate line provided on the base substrate; and a shift register unit provided on the base substrate and located in the side region, an orthographic projection of the shift register unit on the base substrate is located on a side of the orthographic projection of the second common signal line on the base substrate close to the orthographic projection of the display region on the base substrate. The second touch line is arranged in a different layer from the data line and the gate line, and an orthographic projection of at least one second touch line on the base substrate overlaps with the orthographic projection of the shift register unit on the base substrate.

According to the embodiments of the present disclosure, an orthographic projection of the first touch line on the base substrate does not overlap with the orthographic projection of the shift register unit on the base substrate.

According to the embodiments of the present disclosure, the display substrate further includes: a data line and a gate line provided on the base substrate; and a shift register unit provided on the base substrate and located in the side region, an orthographic projection of the shift register unit on the base substrate is located on a side of the orthographic projection of the second common signal line on the base substrate close to the orthographic projection of the display region on the base substrate. The first touch line and the second touch line are arranged in different layers from the data line and the gate line; and an orthographic projection of at least one second touch line on the base substrate overlaps with an orthographic projection of the shift register unit on the base substrate, and an orthographic projection of at least one first touch line on the base substrate overlaps with the orthographic projection of the shift register unit on the base substrate.

According to the embodiments of the present disclosure, the display substrate includes: a plurality of shift register units provided on the base substrate and located in the side region, an orthographic projection of the shift register units on the base substrate is located on a side of the orthographic projection of the second common signal line on the base substrate close to the orthographic projection of the display region on the base substrate; and the plurality of shift register units are arranged in the first direction, a first gap is formed between two adjacent shift register units, and an orthographic projection of at least one second touch line on the base substrate passes through an orthographic projection of the first gap on the base substrate.

According to the embodiments of the present disclosure, an orthographic projection of the M first touch line groups on the base substrate defines a seventh pattern, and the orthographic projection of the first common signal line on the base substrate at least partially surrounds the seventh pattern; an orthographic projection of the N second touch line groups on the base substrate defines an eighth pattern, and the orthographic projection of the second common signal line on the base substrate at least partially surrounds the eighth pattern; and an orthographic projection of the third common signal line on the base substrate at least partially surrounds the orthographic projection of the display region on the base substrate, and either of the orthographic projection of the first common signal line on the base substrate and the orthographic projection of the second common signal line on the base substrate is located on a side of the orthographic projection of the third common signal line on the base substrate away from the orthographic projection of the display region on the base substrate.

According to the embodiments of the present disclosure, an orthographic projection of the M first touch line groups on the base substrate defines a seventh pattern, and the orthographic projection of the first common signal line on the base substrate at least partially surrounds the seventh pattern; an orthographic projection of the N second touch line groups on the base substrate defines an eighth pattern, and the orthographic projection of the second common signal line on the base substrate at least partially surrounds the eighth pattern; and an orthographic projection of the third common signal line on the base substrate at least partially surrounds the orthographic projection of the display region on the base substrate, and either of the orthographic projection of the first common signal line on the base substrate and the orthographic projection of the second common signal line on the base substrate is located on a side of the orthographic projection of the third common signal line on the base substrate close to the orthographic projection of the display region on the base substrate.

According to the embodiments of the present disclosure, an orthographic projection of the M first touch line groups on the base substrate defines a seventh pattern, and the orthographic projection of the first common signal line on the base substrate at least partially surrounds the seventh pattern; an orthographic projection of the N second touch line groups on the base substrate defines an eighth pattern, and the orthographic projection of the second common signal line on the base substrate at least partially surrounds the eighth pattern; an orthographic projection of the third common signal line on the base substrate at least partially surrounds the orthographic projection of the display region on the base substrate; in at least one of the binding region and the binding opposite region, either of the orthographic projection of the first common signal line on the base substrate and the orthographic projection of the second common signal line on the base substrate is located on a side of the orthographic projection of the third common signal line on the base substrate away from the orthographic projection of the display region on the base substrate; and in the side region, either of the orthographic projection of the first common signal line on the base substrate and the orthographic projection of the second common signal line on the base substrate is located on a side of the orthographic projection of the third common signal line on the base substrate close to the orthographic projection of the display region on the base substrate.

According to the embodiments of the present disclosure, an orthographic projection of the M first touch line groups on the base substrate defines a seventh pattern, and the orthographic projection of the first common signal line on the base substrate at least partially surrounds the seventh pattern; an orthographic projection of the N second touch line groups on the base substrate defines an eighth pattern, and the orthographic projection of the second common signal line on the base substrate at least partially surrounds the eighth pattern; an orthographic projection of the third common signal line on the base substrate at least partially surrounds the orthographic projection of the display region on the base substrate; in at least one of the binding region and the binding opposite region, either of the orthographic projection of the first common signal line on the base substrate and the orthographic projection of the second common signal line on the base substrate is located on a side of the orthographic projection of the third common signal line on the base substrate close to the orthographic projection of the display region on the base substrate; and in the side region, either of the orthographic projection of the first common signal line on the base substrate and the orthographic projection of the second common signal line on the base substrate is located on a side of the orthographic projection of the third common signal line on the base substrate away from the orthographic projection of the display region on the base substrate.

According to the embodiments of the present disclosure, the display substrate further includes: a gate line provided on the base substrate; and a common electrode line provided on the base substrate and located in the display region, the common electrode line is connected to the second electrode in the sub-pixel. The third common signal line includes a fifth line segment in the binding opposite region, the fifth line segment is connected to the common electrode line through a sixth transfer structure located in the second transparent electrode layer; the first common signal line includes a first line segment in the binding opposite region, the first line segment and the gate line are arranged in the same layer, and the first touch line and the gate line are arranged in different layers; and a first opening is provided on the sixth transfer structure, an orthographic projection of a part of the first touch line group in the binding opposite region on the base substrate overlaps with an orthographic projection of the first line segment on the base substrate, the first touch line group is connected to the first line segment through a first transfer structure in an overlapping region of the first touch line group and the first line segment, the first transfer structure is located in the second transparent electrode layer, and an orthographic projection of the first transfer structure on the base substrate falls within an orthographic projection of the first opening on the base substrate.

According to the embodiments of the present disclosure, the display substrate further includes: a data line and a gate line provided on the base substrate. The first common signal line includes a first line segment in the binding opposite region, the first line segment and the first touch line are arranged in the same layer, and the first line segment is arranged in a different layer from the data line and the gate line; and in the binding opposite region, the first touch line group is directly connected to the first line segment.

According to the embodiments of the present disclosure, the peripheral region further includes a lead region between the display region and the binding region, and the display substrate further includes a data line, a second common display signal line and a first touch lead provided on the base substrate; the third common signal line includes a seventh line segment in the lead region, an extension direction of the seventh line segment is substantially the same as an extension direction of the second common display signal line, an orthographic projection of the seventh line segment on the base substrate is located on a side of an orthographic projection of the second common display signal line on the base substrate close to the display region, and the seventh line segment is connected to the second common display signal line through a seventh transfer structure located in the second transparent electrode layer; in the lead region, the first touch line is connected to the touch binding end through a first touch lead, the first touch line and the data line are arranged in the same layer, and the first touch lead is arranged in a different layer from the data line; and a second opening is provided on the seventh transfer structure, the first touch line is connected to the first touch lead through a fourth transfer structure located in the second transparent electrode layer, and an orthographic projection of the fourth transfer structure on the base substrate falls within an orthographic projection of the second opening on the base substrate.

According to the embodiments of the present disclosure, the display substrate includes a plurality of data lines, and an orthographic projection of at least one of the plurality of data lines on the base substrate is located between orthographic projections of two adjacent second openings on the base substrate.

According to the embodiments of the present disclosure, the display substrate further includes a display binding end in the binding region and a data lead connected between each of the plurality of data lines and the display binding end; an orthographic projection of a connecting region of the data line and the data lead on the base substrate defines a ninth pattern, and an orthographic projection of the seventh line segment on the base substrate defines a tenth pattern; and the ninth pattern is located on a side of the tenth pattern away from the orthographic projection of the display region on the base substrate.

According to the embodiments of the present disclosure, the first common signal line includes an eighth line segment and a ninth line segment in the lead region, the eighth line segment extends from the first side region toward the touch binding end, and the ninth line segment extends from the second side region toward the touch binding end; the second common signal line includes a tenth line segment and an eleventh line segment in the lead region, the tenth line segment extends from the first side region toward the touch binding end, and the eleventh line segment extends from the second side region toward the touch binding end; and an orthographic projection of the eighth line segment on the base substrate, an orthographic projection of the ninth line segment on the base substrate, an orthographic projection of the tenth line segment on the base substrate and an orthographic projection of the eleventh line segment on the base substrate are located on a side of the ninth pattern away from the display region.

According to the embodiments of the present disclosure, the tenth line segment includes a second sub-line segment, a third sub-line segment and a bending sub-line segment connected between the second sub-line segment and the third sub-line segment, and the second sub-line segment and the third sub-line segment extend in the second direction; and either of the orthographic projection of the eighth line segment on the base substrate and the orthographic projection of the ninth line segment on the base substrate is located between an orthographic projection of the second sub-line segment on the base substrate and an orthographic projection of the third sub-line segment on the base substrate.

According to a second aspect of the present disclosure, a display device is provided, including the display substrate described above.

### BRIEF DESCRIPTION OF THE DRAWINGS

The above contents and other objectives, features and advantages of the present disclosure will be more apparent through the following descriptions of the embodiments of the present disclosure with reference to the accompanying drawings. In the accompanying drawings:

FIG. 1 schematically shows a schematic diagram of a first touch line group in an example;

FIG. 2 schematically shows a schematic diagram of a second touch line group in an example;

FIG. 3 schematically shows a schematic diagram of a third common signal line in an example;

FIG. 4 schematically shows a plan view of a display substrate according to an embodiment of the present disclosure;

FIG. 5 schematically shows a plan view of a first touch line, a first common signal line, a first touch lead and a touch binding end according to an embodiment of the present disclosure;

FIG. 6 schematically shows a plan view of a second touch line, a second common signal line, a second touch lead and a touch binding end according to an embodiment of the present disclosure;

FIG. 7 schematically shows a first schematic diagram of a stacked structure of a display substrate according to an embodiment of the present disclosure;

FIG. 8 schematically shows a first schematic diagram of a third common signal line according to an embodiment of the present disclosure;

FIG. 9 schematically shows a schematic diagram of a touch binding end according to an embodiment of the present disclosure;

FIG. 10 schematically shows a schematic diagram of a second side region according to an embodiment of the present disclosure;

FIG. 11A schematically shows a first schematic diagram of a position relationship between an outermost first touch line group and a third common signal line according to an embodiment of the present disclosure;

FIG. 11B schematically shows a second schematic diagram of a position relationship between an outermost first touch line group and a third common signal line according to an embodiment of the present disclosure;

FIG. 11C schematically shows a third schematic diagram of a position relationship between an outermost first touch line group and a third common signal line according to an embodiment of the present disclosure;

FIG. 12 schematically shows a second schematic diagram of a stacked structure of a display substrate according to an embodiment of the present disclosure;

FIG. 13A and FIG. 13B schematically show a third schematic diagram of a stacked structure of the display substrate according to an embodiment of the present disclosure;

FIG. 14 schematically shows a schematic diagram of a connection between a third common signal line and a connecting line according to an embodiment of the present disclosure;

FIG. 15 schematically shows a schematic diagram of a corner region according to an embodiment of the present disclosure;

FIG. 16 schematically shows a schematic diagram of a first side region according to an embodiment of the present disclosure;

FIG. 17A schematically shows a first schematic diagram of a connection between a second touch line group and a second common signal line according to an embodiment of the present disclosure;

FIG. 17B schematically shows a second schematic diagram of a connection between the second touch line group and a second common signal line according to an embodiment of the present disclosure;

FIG. 18 schematically shows a schematic diagram of a first via hole and a second via hole according to an embodiment of the present disclosure;

FIG. 19 schematically shows a first schematic diagram of a position relationship between a shift register unit and a first common signal line according to an embodiment of the present disclosure;

FIG. 20 schematically shows a second schematic diagram of a position relationship between a shift register unit and a first common signal line according to an embodiment of the present disclosure;

FIG. 21 schematically shows a schematic diagram of providing a second common signal line in a first gap according to an embodiment of the present disclosure;

FIG. 22 schematically shows a second schematic diagram of a third common signal line according to an embodiment of the present disclosure;

FIG. 23A to FIG. 23C schematically show schematic diagrams of a connection between a first touch line group and a first common signal line according to an embodiment of the present disclosure;

FIG. 24A and FIG. 24B schematically show schematic diagrams of a lead region according to an embodiment of the present disclosure;

FIG. 24C schematically shows a schematic diagram of a connection region according to an embodiment of the present disclosure; and

FIG. 25A and FIG. 25B schematically show schematic diagrams of a connection between a first touch line and a first touch lead according to an embodiment of the present disclosure.

### DETAILED DESCRIPTION OF EMBODIMENTS

In order to make objectives, technical solutions and advantages of the embodiments of the present disclosure clearer, the technical solutions of the embodiments of the present disclosure will be clearly and completely described below with reference to the accompanying drawings. Obviously, the described embodiments are merely some embodiments rather than all embodiments of the present disclosure. Based on the described embodiments of the present disclosure, all additional embodiments obtained by those ordinary skilled in the art without carrying out inventive effort fall within the scope of protection of the present disclosure.

It should be noted that in the accompanying drawings, for clarity and/or description purposes, a size and relative size of an element may be enlarged. Accordingly, the size and relative size of each element need not to be limited to those shown in the figures. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, should be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one selected from X, Y or Z” and “at least one selected from a group consisting of X, Y and Z” may be interpreted as only X, only Y, only Z, or any combination of two or more of X, Y and Z, such as XYZ, XY, YZ and ZZ. As used herein, the term “and/or” includes any and all combinations of one or more of the listed related items.

It should be noted that although the terms “first”, “second”, and so on may be used herein to describe various components, members, elements, regions, layers and/or portions, these components, members, elements, regions, layers and/or portions should not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, may be used herein to describe a relationship between an element or feature and another element or feature as shown in the figures. It should be understood that the spatial relationship terms are intended to cover other different orientations of a device in use or operation in addition to the orientation described in the figures. For example, if a device in the figures is turned upside down, an element or feature described as “below” or “under” another element or feature will be oriented “above” or “on” the another element or feature.

Here, the terms “substantially”, “about”, “approximately”, “roughly” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “about” or “approximately” used herein includes a stated value and means that a specific value determined by those ordinary skilled in the art is within an acceptable range of deviation. For example, “about” may mean being within one or more standard deviations, or within ±30%, ±20%, ±10% or ±5% of the stated value.

It should be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions “made of the same material and located in the same layer” are made of the same material and formed by the same patterning process. Generally, a plurality of elements, components, structures and/or portions “made of the same material and located in the same layer” have substantially the same thickness.

Those skilled in the art should understand that, unless otherwise specified, the expression “height” or “thickness” herein refers to a size in a direction perpendicular to a surface of each film layer provided on the display substrate, that is, a size in a light emitting direction of the display substrate, or called a size in a normal direction of the display device.

At present, an electromagnetic touch technology is mainly applied in medium to large-sized screens, and an electromagnetic touch coil may be provided externally on a back side of a display module. For example, an independent circuit board may be added on the back side of the display module, an electromagnetic touch coil may be formed on the circuit board, and the electromagnetic touch coil may match with a stylus to achieve a touch function. The back side of the display module may refer to a backlight side of the display module. Accordingly, the display module further has a display side, which may refer to a light emitting side of the display module.

Exemplarily, the electromagnetic touch coil may be used with a stylus. The electromagnetic touch coil may sense a horizontal movement of the stylus on the display module, and may further sense a distance between the stylus and the display module, so as to achieve a detection of position information in three dimensions (horizontal direction, vertical direction and distance), and then achieve rich pressure-sensitive touch effects and provide a delicate writing experience. However, the external electromagnetic touch coil requires an additional space, so that the entire module is thick and difficult to be thinned.

In an example, a solution is provided to integrate an electromagnetic touch coil into a display module, and the display module may also be referred to as an in cell display module.

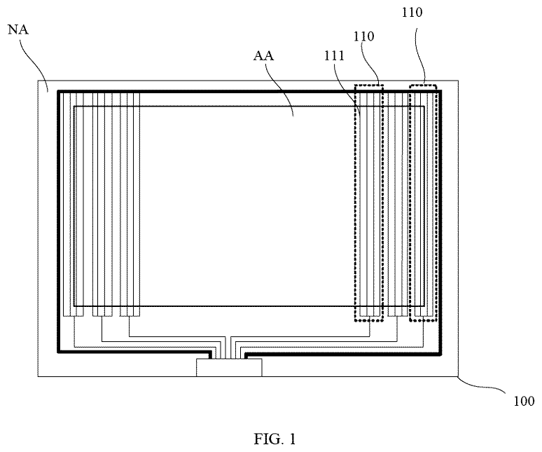

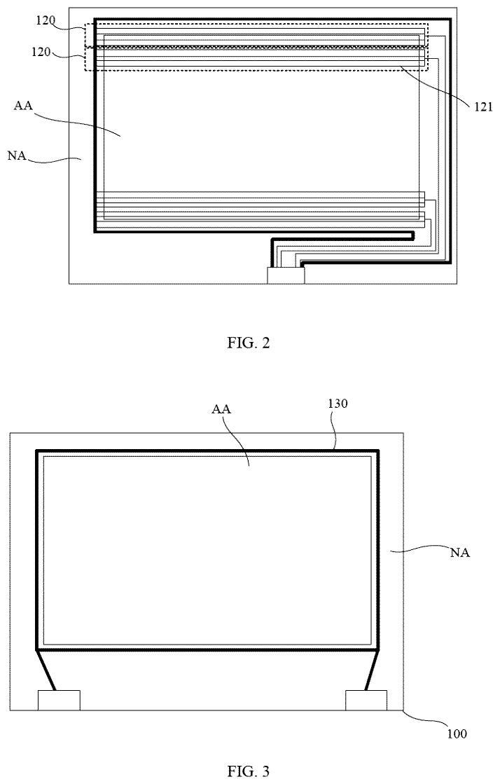

FIG. 1 schematically shows a schematic diagram of a first touch line group in an example. FIG. 2 schematically shows a schematic diagram of a second touch line group in an example. FIG. 3 schematically shows a schematic diagram of a third common signal line in an example, where the third common signal line may also be referred to as a common display signal line.

With reference to FIG. 1 to FIG. 3, in this example, a display module 100 includes a display region AA and a peripheral region NA at least partially surrounding the display region AA. The display region AA is provided with touch line groups, each of the touch line groups includes a plurality of touch lines connected in parallel. For example, the touch line groups include a plurality of first touch line groups 110 extending vertically and a plurality of second touch line groups 120 extending horizontally. A first touch line group 110 includes a plurality of first touch lines 111 connected in parallel, and each first touch line group 110 has a same wire arrangement. A second touch line group 120 includes a plurality of second touch lines 121 connected in parallel, and each second touch line group 120 has a same wire arrangement. Taking the first touch line groups 110 as an example, during a touch detection, at least two first touch line groups 110 are energized, then the energized first touch line groups 110 may form a vertical electromagnetic touch coil. Similarly, the second touch line groups 120 may form a horizontal electromagnetic touch coil. The electromagnetic touch coil may sense an electromagnetic signal according to a touch object (e.g., a stylus), and the electromagnetic signal may be analyzed to achieve a touch recognition.

In order to improve a touch detection accuracy at an edge of the display region AA, in this example, it is desired that an outermost first touch line group 110 is located in both the display region AA and the peripheral region NA, as shown by the rightmost (or leftmost) first touch line group 110 shown in FIG. 1. However, there may be a wire conflict between the outermost first touch line group 110 and a wire originally located in this region.

The wire conflict is embodied in two aspects. In a first aspect, a third common signal line 130 is provided in the peripheral region NA to surround the display region AA, and on left and right sides of the display region AA, the third common signal line 130 and the first touch line 111 are arranged in the same layer, so that the first touch line 111 in the outermost first touch line group 110 is easily short-circuited with the third common signal line 130.

In a second aspect, a traditional in cell display module 100 generally has a capacitive touch structure, and the electromagnetic touch coil is more sensitive to a signal crosstalk than the capacitive touch structure. On one hand, the electromagnetic touch coil is more susceptible to interference from a surrounding signal line, and on the other hand, the electromagnetic touch coil is also easier to interfere with a surrounding signal line. Therefore, when providing the outermost first touch line group 110, it is not only needed to face the short-circuit between the first touch line 111 and the third common signal line 130, but also needed to face a crosstalk between the first touch line 111 and the third common signal line 130. The crosstalk may lead to difficulty in achieving an expected improvement in a touch detection accuracy at the edge of the display region AA, and may even affect a display effect.

In view of this, the embodiments of the present disclosure provide a display substrate, including a display region and a peripheral region at least partially surrounding the display region. The peripheral region includes a binding region and a binding opposite region opposite to each other in a first direction and two side regions opposite to each other in a second direction intersecting with the first direction. The display substrate further includes: a base substrate; a second transparent electrode layer provided on the base substrate; a first conductive layer and a second conductive layer that are provided on the base substrate, where the first conductive layer and the second conductive layer are located between the base substrate and the second transparent electrode layer; a sub-pixel provided on the base substrate and located in the display region, where the sub-pixel includes a second electrode in the second transparent electrode layer; a third common signal line provided on the base substrate and located in the peripheral region, where the third common signal line may also be referred to as a common display signal line; M first touch line groups and N second touch line groups provided on the base substrate, where the M first touch line groups are arranged in the second direction, and the N second touch line groups are arranged in the first direction. The first touch line group includes at least one first touch line, and the first touch lines in one and same first touch line group are connected in parallel. The second touch line group includes at least one second touch line, and the second touch lines in one and same second touch line group are connected in parallel. The first touch line is located in the first conductive layer, the second touch line is located in the second conductive layer, and the first touch line is insulated and spaced apart from the second touch line. In an outermost first touch line group among the M first touch line groups, a part of the first touch lines are located in the display region, the other part of the first touch lines are located in the side region, and the first touch line and the third common signal line are arranged such that: the first touch line and a part of the third common signal line in the side region are located in the same layer and are spaced apart from each other, or the first touch line and the part of the third common signal line in the side region are located in different layers. M and N are positive integers.

Through the above-mentioned arrangement, in the side region, the outermost first touch line group may cover a boundary of the display region and the side region, so that a sensing range of the electromagnetic touch coil formed by a first touch line group Z1 may be expanded, and the touch detection accuracy at the edge of the display region may be improved. Furthermore, in the outermost first touch line group, the first touch lines and the part of the third common signal line in the side region are located in the same layer and are spaced apart from each other (or located in different layers), which may not only prevent short-circuit between the first touch line and the third common signal line, but also prevent crosstalk between the first touch line and the third common signal line. Thus, the wire conflict between the first touch line and the third common signal line is overcome, which may help to achieve an expected improvement of the touch detection accuracy at the edge of the display region, and also reduce an influence on the display effect.

The display substrate of the embodiments of the present disclosure will be described in detail below.

FIG. 4 schematically shows a plan view of a display substrate according to an embodiment of the present disclosure.

Referring to FIG. 4, the display substrate in the embodiments of the present disclosure includes a display region AA and a peripheral region NA on at least one side of the display region AA.

The display region AA may have various shapes. For example, the display region AA may be provided in various shapes such as a closed polygon including straight sides (e.g., a rectangle), a circle or an ellipse, etc. including a curved side, and a semicircle or a semi-ellipse, etc. including a straight side and a curved side. In the embodiments of the present disclosure, the display region AA is provided as a region having a quadrangular shape including straight sides. It should be understood that this is merely an exemplary embodiment of the present disclosure rather than a limitation to the present disclosure.

The display substrate may further include a base substrate 200 and a plurality of pixel units P provided on the base substrate 200 and located in the display region AA. The plurality of pixel units P may be arranged in an array in a first direction Y and a second direction X. The first direction Y may intersect with the second direction X. For example, the first direction Y may be a vertical direction in FIG. 4, and the second direction X may be a horizontal direction in FIG. 4, that is, the first direction Y and the second direction X are perpendicular to each other.

Each pixel unit P may include a plurality of sub-pixels PX. For example, the pixel unit P may include a first sub-pixel, a second sub-pixel and a third sub-pixel. Exemplarily, the first sub-pixel, the second sub-pixel and the third sub-pixel may be respectively provided as a red sub-pixel, a green sub-pixel and a blue sub-pixel, but the embodiments of the present disclosure are not limited to this.

Referring to FIG. 4, the plurality of sub-pixels PX may be arranged in an array in the first direction Y and the second direction X, but the embodiments of the present disclosure are not limited to this. For ease of description, in the embodiments of the present disclosure, a plurality of sub-pixels PX arranged in the first direction Y are referred to as a column of sub-pixels PX, and a plurality of sub-pixels PX arranged in the second direction X are referred to as a row of sub-pixels PX.

The display substrate further includes a plurality of gate lines GL and a plurality of data lines DL provided on the base substrate 200 and located in at least the display region AA. The plurality of data lines DL extend in the first direction Y, and the plurality of gate lines GL extend in the second direction X. Exemplarily, a sub-pixel PX is connected to a data line DL and a gate line GL, a row of sub-pixels PX are connected to one and same gate line GL, different rows of sub-pixels PX are connected to different gate lines GL, a column of sub-pixels PX are connected to one and same data line DL, and different columns of sub-pixels PX are connected to different data lines DL.

The peripheral region NA may be provided on at least one side of the display region AA. For example, the peripheral region NA may surround a periphery of the display region AA. In the embodiments of the present disclosure, the peripheral region NA may include a vertical portion extending in the first direction Y and a horizontal portion extending in the second direction X.

The display substrate may further include a gate driving circuit 21 and a display binding end PAD1, which are provided on the base substrate 200 and located in the peripheral region NA. For example, the gate driving circuit 21 may be located on at least one side of the display region AA. In the embodiments shown in FIG. 4, the gate driving circuit 21 is located on a left side and a right side of the display region AA, respectively. It should be noted that the left side and the right side may refer to a left side and a right side of the display substrate (screen) viewed by human eyes during display. For example, the display binding end PAD1 may be located on at least one side of the display region AA. In the embodiments shown in FIG. 4, the display binding end PAD1 is located on a lower side of the display region AA. It should be noted that the lower side may be a lower side of the display substrate (screen) viewed by human eyes during display.

The display binding end PAD1 is electrically connected to a display driver chip (not shown). Exemplarily, the display binding end PAD1 and the display driver chip may be directly connected through binding, etc. Alternatively, the display binding end PAD1 and the display driver chip may be connected through a flexible circuit board or other devices. The display driver chip includes a data driving circuit, which is used to regularly latch input data in sequence according to clock signal, convert the latched data into an analog signal and then input the analog signal to each data line DL of the display substrate. The gate driving circuit 21 is generally implemented by a shift register unit which converts a clock signal into an on/off voltage and outputs the on/off voltage to each gate line GL of the display substrate respectively.

It should be noted that FIG. 1 shows that the gate driving circuit 21 is located on the left side and the right side of the display region AA, and the display binding end PAD1. is located on the lower side of the display region AA. However, the embodiments of the present disclosure are not limited thereto. The gate driving circuit 21 and the display binding end PAD1 may be located at any suitable position in the peripheral region NA.

Exemplarily, the GOA technology, namely Gate Driver on Array, may be adopted for the gate driving circuit 21. In the GOA technology, the gate driving circuit 21 is provided directly on an array substrate to replace an external chip. Each GOA unit serves as a stage of shift register unit, and each stage of shift register unit is connected to a gate line GL. Scanning signals are sequentially output in turn through stages of shift register units to achieve progressive scanning of sub-pixels PX. In some embodiments, each stage of shift register unit may also be connected to a plurality of gate lines GL. In this way, it may adapt to a development trend of high resolution and narrow bezel of the display substrate.

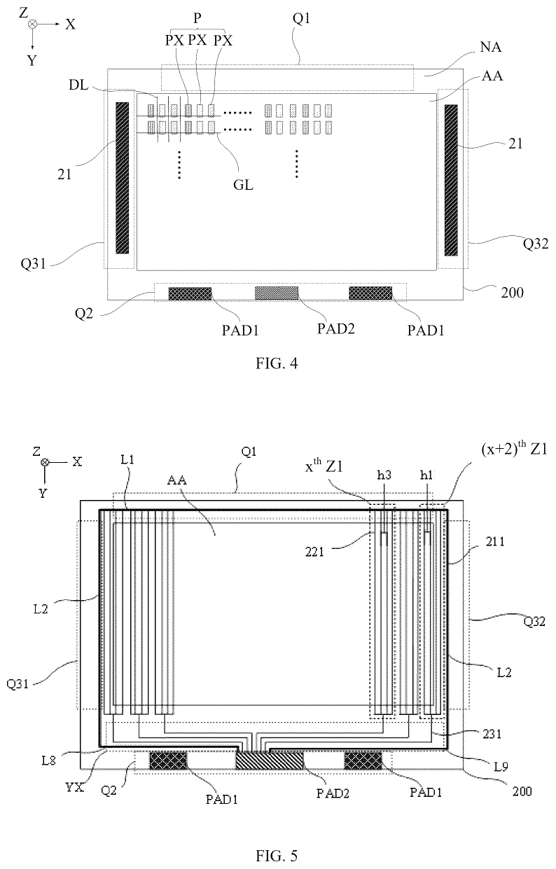

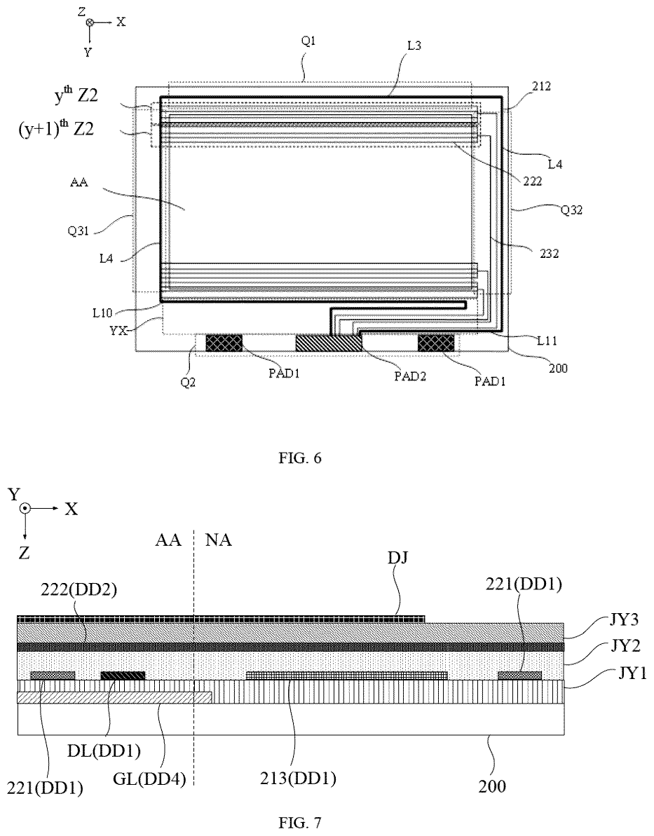

FIG. 5 schematically shows a plan view of a first touch line, a first common signal line, a first touch lead and a touch binding end according to an embodiment of the present disclosure, and FIG. 6 schematically shows a plan view of a second touch line, a second common signal line, a second touch lead and a touch binding end according to an embodiment of the present disclosure.

With reference to FIG. 4 to FIG. 6, in the embodiments of the present disclosure, the peripheral region NA includes a binding opposite region Q1 and a binding region Q2 opposite to each other in the first direction Y, and the display binding end PAD1 is provided in the binding region Q2. In addition, a touch binding end PAD2 is further provided in the binding region Q2. The peripheral region NA further includes two side regions opposite to each other in the second direction X. For example, the peripheral region NA includes a first side region Q31 on the left side of the display region AA and a second side region Q32 on the right side of the display region AA.

The touch binding end PAD2 may electrically connect a signal line used to achieve a touch function on the display substrate to a touch detection chip (not shown). The touch detection chip may be provided at any suitable position on the display substrate. For example, the touch detection chip may be provided on a back side of the display substrate. The signal line used to achieve the touch function includes a first common signal line 211, a second common signal line 212, a first touch line 221 and a second touch line 222 that will be mentioned below. The back side of the display substrate may refer to a backlight side of the display substrate. Accordingly, the display substrate further has a display side, which may refer to a light emitting side of the display substrate.

Optionally, a plurality of display binding ends PAD1 may be provided. For example, two display binding ends PAD1 may be provided, and the touch binding end PAD2 is located between the two display binding ends PAD1 in the second direction X.

The display substrate further includes a first common signal line 211 and a second common signal line 212 provided on the base substrate 200. The first common signal line 211 and the second common signal line 212 are both located in the peripheral region NA.

The first common signal line 211 may be arranged at least partially around the display region AA. For example, referring to FIG. 5, the first common signal line 211 surrounds at least upper, left and right sides of the display region AA, and is connected to the touch binding end PAD2 on the lower side of the display region AA. For another example, the first common signal line 211 completely surrounds the display region AA, in other words, the first common signal line 211 continuously surrounds the display region AA, and is connected to the touch binding end PAD2 on the lower side of the display region AA. The second common signal line 212 may be arranged at least partially around the display region AA. For example, referring to FIG. 6, the second common signal line 212 surrounds at least the upper, left and right sides of the display region AA, and is connected to the touch binding end PAD2 on the lower side of the display region AA. For another example, the second common signal line 212 completely surrounds the display region AA, in other words, the second common signal line 212 continuously surrounds the display region AA, and is connected to the touch binding end PAD2 on the lower side of the display region AA.

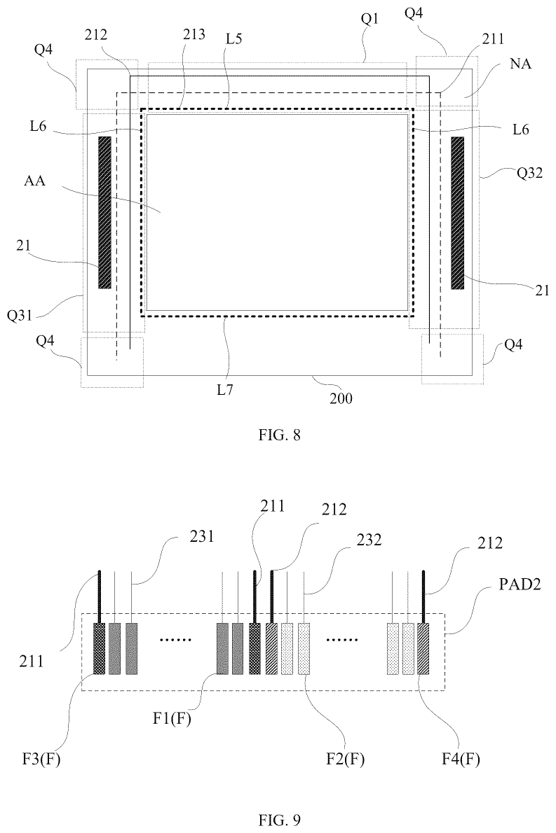

FIG. 7 schematically shows a first schematic diagram of a stacked structure of a display substrate according to an embodiment of the present disclosure, and FIG. 8 schematically shows a first schematic diagram of a third common signal line according to an embodiment of the present disclosure.

With reference to FIG. 7 and FIG. 8, the display substrate further includes a second transparent electrode layer DJ, a first conductive layer DD1, a second conductive layer DD2, a third common signal line 213, M first touch line groups Z1 and N second touch line groups Z2, which are provided on the base substrate 200, where the third common signal line 213 may also be referred to as a common display signal line, and M and N are positive integers. The first conductive layer DD1 and the second conductive layer DD2 are located between the second transparent electrode layer DJ and the base substrate 200, and the third common signal line 213 is located in the peripheral region NA.

In the embodiments of the present disclosure, the sub-pixel PX includes a second electrode located in the second transparent electrode layer DJ. For example, the display substrate in the embodiments of the present disclosure may be applied to a liquid crystal display panel, and the second electrode may be a common electrode. Accordingly, the sub-pixel further includes a first electrode, and the first electrode may be a pixel electrode. The first electrode may be provided in one of conductive film layers between the second transparent electrode layer DJ and the base substrate 200. For example, the display substrate further includes a first transparent electrode layer between the second transparent electrode layer DJ and the base substrate 200, and the first electrode is located in the first transparent electrode layer. The second transparent electrode layer DJ and the first transparent electrode layer may be made of transparent conductive materials, such as indium tin oxide (ITO).

Exemplarily, the liquid crystal display panel includes a liquid crystal layer provided on a side of the second transparent electrode layer DJ away from the base substrate 200. The second electrode and the first electrode may apply a first electric field in response to a driving signal, and liquid crystal molecules in the liquid crystal layer may be deflected under a drive of the first electric field, so that a display function may be achieved.

With reference to FIG. 5 and FIG. 6, the first touch line group Z1 includes at least one first touch line 221, and the second touch line group Z2 includes at least one second touch line 222. The first touch line 221 is located in the first conductive layer DD1, and the second touch line 222 is located in the second conductive layer DD2. The first touch line group Z1 and the second touch line group Z2 are respectively used to form an electromagnetic touch coil extending vertically and an electromagnetic touch coil extending horizontally. The first conductive layer DD1 and the second conductive layer DD2 are located between the base substrate 200 and the second transparent electrode layer DJ, that is, the electromagnetic touch coils in the embodiments of the present disclosure are integrated on the display substrate.

The M first touch line groups Z1 are arranged in the second direction X, and the N second touch line groups Z2 are arranged in the first direction Y. The first touch lines 221 in one and same first touch line group Z1 are connected in parallel, the second touch lines 222 in one and same second touch line group Z2 are connected in parallel, and the first touch lines 221 are insulated and spaced apart from the second touch lines 222. The first touch lines 221 extend in the first direction Y, and the second touch lines 222 extend in the second direction X.

Exemplarily, the display substrate further includes at least one insulation layer between the first conductive layer DD1 and the second conductive layer DD2. The insulation layer may insulate and separate the first touch line 221 from the second touch line 222, so that the first touch line 221 is insulated and spaced apart from the second touch line 222. The insulation layer will be described in detail below and will not be explained here.

Optionally, the first touch line 221 may not only be located in the display region AA, but may also extend to a periphery of the display region AA in the first direction Y to increase a touch detection area of the first touch line group Z1. The second touch line 222 may not only be located in the display region AA but also extend to the periphery of the display region AA in the second direction X to increase a touch detection area of the second touch line group Z2.

The first touch line 221 has a first end electrically connected to the first common signal line 211 and a second end electrically connected to the touch binding end PAD2. For example, the second end of the first touch line 221 is electrically connected to the touch binding end PAD2 through a first touch lead 231. The second touch line 222 has a first end electrically connected to the second common signal line 212 and a second end electrically connected to the touch binding end PAD2. For example, the second end of the second touch line 222 is electrically connected to the touch binding end PAD2 through a second touch lead 232.

Referring to FIG. 5, the first end and the second end of the first touch line 221 may refer to upper and lower ends of the first touch line 221, respectively. Referring to FIG. 6, the first end and the second end of the second touch line 222 may refer to left and right ends of the second touch line 222, respectively.

FIG. 9 schematically shows a schematic diagram of the touch binding end according to an embodiment of the present disclosure.

Referring to FIG. 9, in the embodiments of the present disclosure, the touch binding end PAD2 includes a plurality of sensing terminals F. The M first touch line groups Z1 are electrically connected to different sensing terminals F from the N second touch line groups Z2, different first touch line groups Z1 are electrically connected to different sensing terminals F, and different second touch line groups Z2 are electrically connected to different sensing terminals F.

For example, the touch binding end PAD2 includes a plurality of first sensing terminals F1, and the first touch lines 221 in one and same first touch line group Z1 are electrically connected to one and same first sensing terminal F1 through one and same first touch lead 231. The touch binding end PAD2 includes a plurality of second sensing terminals F2, and the second touch lines 222 in one and same second touch line group Z2 are electrically connected to one and same second sensing terminal F2 through one and same second touch lead 232.

In the embodiments of the present disclosure, the touch binding end PAD2 may be bonded and connected to a first flexible circuit board, and then electrically connected to the touch detection chip through the first flexible circuit board. The touch detection chip may scan the first touch line group Z1 and the second touch line group Z2 to detect a position of the touch object.

Exemplarily, the touch detection chip may be selectively conducted with the sensing terminals F on the touch binding end PAD2 according to a predetermined scanning timing, so as to achieve a scanning of the first touch line groups Z1 and the second touch line groups Z2.

Exemplarily, the touch detection chip may scan the first touch line groups Z1 in the second direction X and scan the second touch line groups Z2 in the first direction Y. When scanning the first touch line groups Z1, the touch detection chip may be conducted with i first touch line groups Z1 during each scanning, where i is a positive integer and i≥2. When scanning the second touch line groups Z2, the touch detection chip may be conducted with j second touch line groups Z2 during each scanning, where j is a positive integer and j≥2.

Taking i=j=2 as an example, when scanning the first touch line groups Z1, the touch detection chip is conducted with two first touch line groups Z1 during each scanning, and the two first touch line groups Z1 may form a vertical electromagnetic touch coil (hereinafter also referred to as a first electromagnetic touch coil). When scanning the second touch line groups Z2, the touch detection chip is conducted with two second touch line groups Z2 during each scanning, and the two second touch line groups Z2 may form a horizontal electromagnetic touch coil (hereinafter also referred to as a second electromagnetic touch coil).

Exemplarily, when scanning the first touch line groups Z1, the touch detection chip is conducted with an x^{th} first touch line group Z1 and an (x+2)^{th} first touch line group Z1 during each scanning, where x=1,2,3, . . . , M-4,M-2. In this way, it is possible to sequentially form a plurality of first electromagnetic touch coils in the second direction X, and two first electromagnetic touch coils formed consecutively may overlap with each other, which helps to reduce a detection blind spot of the first electromagnetic touch coil. When scanning the second touch line groups Z2, the touch detection chip is conducted with a y^{th} second touch line group Z2 and a (y+2)^{th} second touch line group Z2, where y=1,2,3, . . . , N-4,N-2. In this way, it is possible to sequentially form a plurality of second electromagnetic touch coils in the first direction Y, and two second electromagnetic touch coils formed consecutively may overlap each other, which helps to reduce a detection blind spot of the second electromagnetic touch coil.

When a touch object (such as a stylus) performs a touch action on the display substrate, the electromagnetic touch coil at a corresponding position may sense a corresponding electromagnetic signal, including but not limited to changes in amplitude and frequency, and the touch detection chip may determine the position of the touch object by analyzing the electromagnetic signal. For example, the touch detection chip may determine coordinates of the touch object in the first direction Y by analyzing the electromagnetic signal sensed by the first electromagnetic touch coil, and determine coordinates of the touch object in the second direction X by analyzing the electromagnetic signal sensed by the second electromagnetic touch coil, and then determine the position of the touch object based on these two coordinates.

It should be noted that the above values of i, j, x and y are merely exemplary illustrations, and do not constitute limitations to the embodiments of the present disclosure. For example, a value of i may also be 4 or 6 and so on, as long as a suitable electromagnetic touch coil may be formed. When scanning the first touch line groups Z1, the first touch line groups Z1 that are conducted each time are not limited to the above form. For example, the touch detection chip may also be conducted with the x^{th} first touch line group Z1 and an (x+1)^{th} first touch line group Z1 during each scanning. Similarly, when scanning the second touch line groups Z2, the second touch line groups Z2 that are conducted each time are not limited to the above form.

It should also be noted that, because the first touch line group Z1 and the second touch line group Z2 are electrically connected to the touch detection chip through different sensing terminals F, the touch detection chip may scan the first touch line group Z1 and the second touch line group Z2 in a time-sharing manner, or scan the first touch line group Z1 and the second touch line group Z2 simultaneously. When the touch detection chip scans the first touch line group Z1 and the second touch line group Z2 in a time-sharing manner, a crosstalk between the first touch line group Z1 and the second touch line group Z2 may be reduced.

In this way, the electromagnetic touch coils used to achieve the touch function may be integrated on the display substrate, which may help thinning and lightening of the display product.

In the outermost first touch line group among the M first touch line groups Z1, a part of first touch lines 221 is located in the display region AA, and the other part of first touch lines 221 is located in the side region. For example, referring to FIG. 5, the outermost first touch line group Z1 may refer to a leftmost first touch line group Z1 and a rightmost first touch line group Z1 among the M first touch line groups Z1.

The M first touch line groups ZI are arranged sequentially from a left edge of the display region AA to a right edge of the display region AA, so that a touch detection range of the M first touch line groups Z1 may cover an entire display region AA. Since a part of first touch lines 221 in the outermost first touch line group Z1 is located in the display region AA and the other part first touch lines 221 is located in the peripheral region NA, the outermost first touch line group Z1 may cover a boundary of the display region AA and the peripheral region NA, so that the touch detection accuracy at the edge of the display region AA may be improved.

The third common signal line 213 is located in the peripheral region NA and at least partially surrounds the display region AA. As the outermost first touch line group Z1 is located at the edge of the display region AA, the outermost first touch line group Z1 is closest to the third common signal line 213, and the outermost first touch line group Z1 is most prone to crosstalk with the third common signal line 213. Accordingly, in the embodiments of the present disclosure, the first touch lines 221 and the third common signal line 213 are arranged in one of the following manners.

In a first manner, the first touch lines 221 and a part of the third common signal line 213 in the side region are located in a same layer and spaced apart from each other.

In a second manner, the first touch lines 221 and the part of the third common signal line 213 in the side region are located in different layers.

Through the above-mentioned manners, it is possible to form a sufficient distance between the first touch lines 221 in the outermost first touch line group Z1 and the third common signal line 213, so as to avoid short-circuit between these first touch lines 221 and the third common signal line 213 and also avoid crosstalk between these first touch lines 221 and the third common signal line 213.

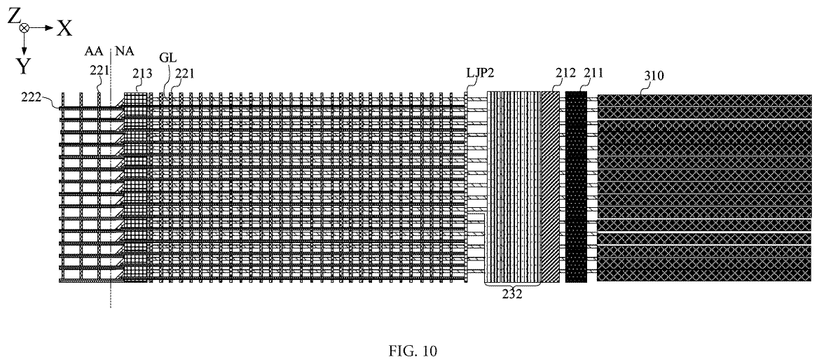

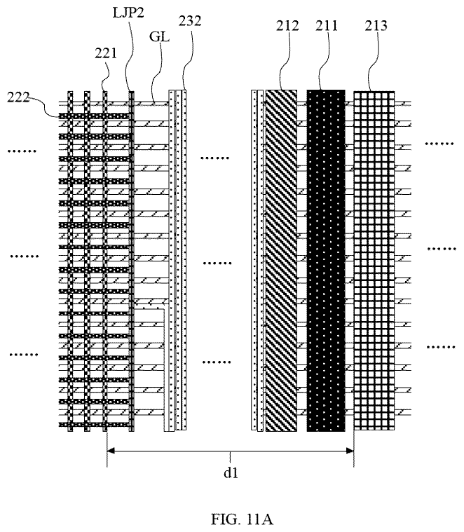

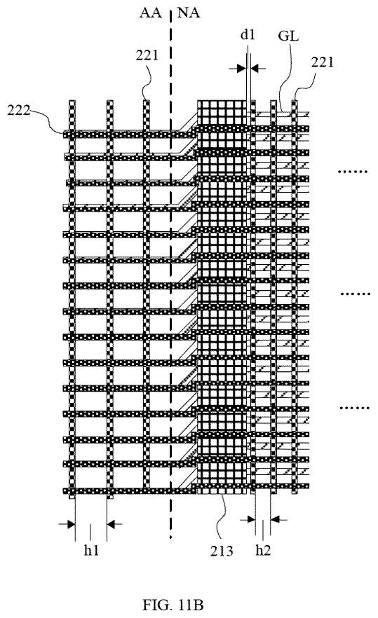

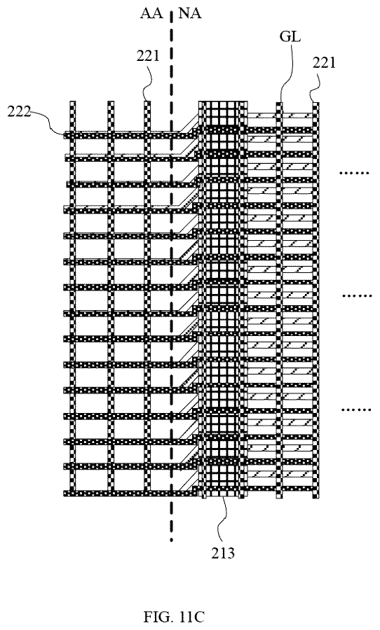

FIG. 10 schematically shows a schematic diagram of a second side region according to an embodiment of the present disclosure. FIG. 11A schematically shows a first schematic diagram of a position relationship between the outermost first touch line group and the third common signal line according to an embodiment of the present disclosure.

With reference to FIG. 10 and FIG. 11A, in some specific embodiments, the part of the third common signal line 213 in the side region is arranged in the same layer as the first touch lines 221. For example, the part of the third common signal line 213 in the side region and the first touch lines 221 are located in the first conductive layer DD1.

In an example, the third common signal line 213 may avoid the outermost first touch line group Z1. For example, in the second side region Q32, the third common signal line 213 is moved toward a side away from the display region AA, so that the third common signal line 213 is away from a region where the outermost first touch line group Z1 is located, and a minimum distance between the first touch lines 221 and the third common signal line 213 is sufficiently large. In this example, a wire arrangement of the outermost first touch line group Z1 may remain unchanged, which may help improve an uniformity of the touch detection.

FIG. 11B schematically shows a second schematic diagram of a position relationship between the outermost first touch line group and the third common signal line according to an embodiment of the present disclosure.

With reference to FIG. 10 and FIG. 11B, in another example, it is possible to adjust an arrangement of the first touch lines 221 in the outermost first touch line group Z1 so that the first touch lines 221 avoid the third common signal line 213. For example, it is possible to reduce a wire distance between the first touch lines 221 in the side region so that the wire distance between the first touch lines 221 in the side region is less than a wire distance between the first touch lines 221 in the display region AA, then the first touch lines 221 in the side region may be arranged denser, and a minimum distance d1 between the first touch lines 221 and the third common signal line 213 in the side region is sufficiently large. Alternatively, it is also possible to move the first touch lines 221 in the side region as a whole toward a side away from the display region AA, so that the minimum distance d1 between the first touch lines 221 and the third common signal line 213 in the side region is sufficiently large. In this example, only the first touch lines 221 in the side region in the outermost first touch line group Z1 are changed, and the third common signal line 213 and its related wires may remain unchanged, then a magnitude of change is greatly reduced.

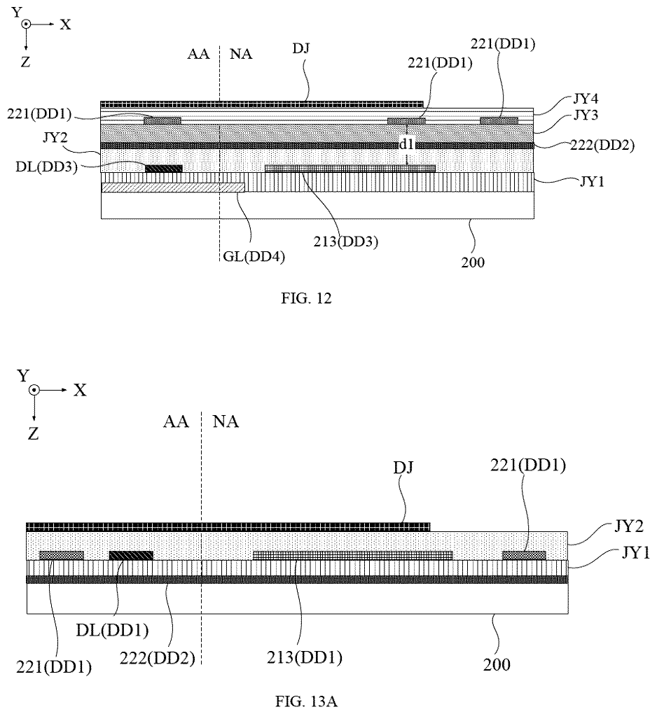

FIG. 11C schematically shows a third schematic diagram of a position relationship between the outermost first touch line group and the third common signal line according to an embodiment of the present disclosure. FIG. 12 schematically shows a second schematic diagram of a stacked structure of the display substrate according to an embodiment of the present disclosure.

With reference to FIG. 10, FIG. 11C and FIG. 12, in some other specific embodiments, the part of the third common signal line 213 in the side region is arranged in a different layer from the first touch lines 221. For example, the third common signal line 213 may be located in an original conductive film layer. For example, in this example, a layer where the part of the third common signal line 213 in the side region is located may be referred to as a third conductive layer DD3, and an additional conductive film layer may be provided on the display substrate as the first conductive layer DD1. Then, through an insulation layer and other structures provided between the first conductive layer DD1 and the second conductive layer DD2, the minimum distance between the first touch lines 221 and the third common signal line 213 may also be sufficiently large. In this example, the first touch line group Z1 and the third common signal line 213 have a greater degree of freedom in wiring, the third common signal line 213 and its related signal lines may remain unchanged, and the wiring arrangement of the first touch line group Z1 may also remain unchanged. Alternatively, in the first touch line group Z1, the wire distance between the first touch lines 221 in the display region AA may be identical with the wire distance between the first touch lines 221 in the side region. It should be noted that since the part of the third common signal line 213 in the side region is arranged in a different layer from the first touch lines 221, the part of the third common signal line 213 in the side region may overlap with the first touch lines 221. Herein, the “first touch lines 221 in the side region” includes both the first touch lines 221 that overlap with the part of the third common signal line 213 in the side region and the first touch lines 221 that do not overlap with the part of the third common signal line 213 in the side region. In other words, in the first touch line group Z1, no matter whether the first touch lines 221 overlap with the part of the third common signal line 213 located in the side region, these first touch lines 221 are evenly spaced, and the wire distance between these first touch lines 221 in the side region is identical with the wire distance between the first touch lines 221 in the first touch line group Z1 in the display region, which may help improve the wire uniformity.

Optionally, in this example, in the first touch line group Z1, the wire distance between the first touch lines 221 in the display region AA is identical with a wire width of the first touch lines 221 in the side region. As described above, the “first touch lines 221 in the side region” here includes both the first touch lines 221 that overlap with the part of the third common signal line 213 located in the side region and the first touch lines 221 that do not overlap with the part of the third common signal line 213 located in the side region. In other words, in the first touch line group Z1, no matter whether the first touch lines 221 overlap with the part of the third common signal line 213 located in the side region, these first touch lines 221 have the same wire width, and the wire width of these first touch lines 221 in the side region is identical with the wire width of the first touch lines 221 in the first touch line group Z1 in the display region AA, which helps improve the wire uniformity.

In summary, in the embodiments of the present disclosure, the outermost first touch line group Z1 is located in both the display region AA and the peripheral region NA, so that the sensing range of the electromagnetic touch coil formed by the first touch line group Z1 may be expanded, and then the touch detection accuracy at the edge of the display region AA may be improved. Moreover, in the outermost first touch line group Z1, the first touch lines 221 and the part of the third common signal line 213 in the side region are located in the same layer and spaced apart from each other (or located in different layers), so as to prevent short-circuit between these first touch lines 221 and the third common signal line 213 and also prevent crosstalk between these first touch lines 221 and the third common signal line 213. Thus, the wiring conflict between these first touch lines 221 and the third common signal line 213 is overcome, which may help to achieve an expected improvement of the touch detection accuracy at the edge of the display region AA and also reduce the influence on the display effect.

The display substrate of the embodiments of the present disclosure will be further described below with reference to FIG. 4 to FIG. 25B.

In the embodiments of the present disclosure, the display substrate may include at least three stacked structures.

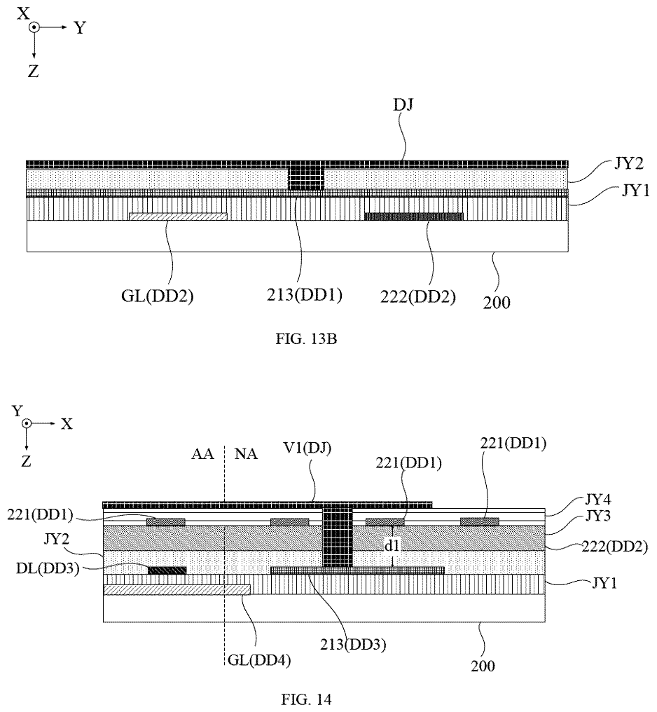

FIG. 13A and FIG. 13B schematically show a third schematic diagram of a stacked structure of the display substrate according to an embodiment of the present disclosure.

Exemplarily, with reference to FIG. 13A and FIG. 13B, in a first stacked structure, when the first touch lines 221 and the second touch lines 222 are arranged, the existing conductive film layers may be maximally reused. For example, the first touch lines 221 may be arranged in the same layer as the data lines DL, and the second touch lines 222 may be arranged in the same layer as the gate lines GL. For example, the display substrate includes a second conductive layer DD2, a gate insulation layer JY1, a first conductive layer DD1, a second insulation layer JY2 and a second transparent electrode layer DJ arranged sequentially in a direction away from the base substrate 200. The first touch lines 221 and the data lines DL are located in the first conductive layer DD1, and the second touch lines 222 and the gate lines GL are located in the second conductive layer DD2.

Exemplarily, referring to FIG. 7, in a second stacked structure, the second touch lines 222 are located separately in a conductive film layer to increase a wire flexibility. For example, the display substrate includes a fourth conductive layer DD4, a gate insulation layer JY1, a first conductive layer DD1, a second insulation layer JY2, a second conductive layer DD2, a third insulation layer JY3 and a second transparent electrode layer DJ arranged sequentially in a direction away from the base substrate 200. The gate lines GL are located in the fourth conductive layer DD4, the first touch lines 221 and the data lines DL are located in the first conductive layer DD1, and the second touch lines 222 are located in the second conductive layer DD2. In this example, it is equivalent to adding a conductive film layer as the second conductive layer DD2 on a side of the layer where the data lines DL are located away from the base substrate 200, and the second touch lines 222 may be located separately in the second conductive layer DD2.

Exemplarily, referring to FIG. 12, in a third stacked structure, the first touch lines 221 and the second touch lines 222 are respectively located separately in a conductive film layer to better increase the wire flexibility. For example, the display substrate includes a fourth conductive layer DD4, a gate insulation layer JY1, a third conductive layer DD3, a second insulation layer JY2, a second conductive layer DD2, a third insulation layer JY3, a first conductive layer DD1, a first insulation layer JY4 and a second transparent electrode layer DJ arranged sequentially in a direction away from the base substrate 200. The gate lines GL are located in the fourth conductive layer DD4, the data lines DL are located in the third conductive layer DD3, the first touch lines 221 are located in the first conductive layer DD1, and the second touch lines 222 are located in the second conductive layer DD2. In this example, it is equivalent to respectively adding two conductive film layers as the first conductive layer DD1 and the second conductive layer DD2 on a side of the layer where the data lines DL are located away from the base substrate 200. The first touch lines 221 may be located separately in the first conductive layer DD1, and the second touch lines 222 may be located separately in the second conductive layer DD2.

For clarity of description, unless otherwise specified, the display substrate of the embodiments of the present disclosure will be described below taking the second stacked structure as an example. It should be understood that, when a particular structure is described below, unless otherwise specified, the structure may be applied in a same form to the first stacked structure and the third stacked structure. It should also be noted that in the present disclosure, unless otherwise specified, two structures overlapping with each other specifically refers to that orthographic projections of the two structures on the base substrate 200 overlap with each other.

Referring to FIG. 11B, in some specific embodiments, the first touch lines 221 and the part of the third common signal line 213 in the side region are arranged in the same layer. An orthographic projection of the part of the third common signal line 213 in the side region on the base substrate 200 defines a first pattern. In the outermost first touch line group Z1 among the M first touch line groups Z1, an orthographic projection of the first touch lines 221 in the display region AA on the base substrate 200 defines a second pattern, an orthographic projection of the first touch lines 221 in the side region on the base substrate 200 defines a third pattern, and the first pattern is located between the second pattern and the third pattern.

The third common signal line 213 passes through the outermost first touch line group Z1. Taking the second side region Q32 as an example, in the outermost first touch line group Z1, the first touch lines 221 in the display region AA are located on the left side of the third common signal line 213, and the first touch lines 221 in the peripheral region NA are located on the right side of the third common signal line 213. Compared with the display region AA, the number of signal lines (for example, data lines DL) extending in the same direction as the first touch lines 221 in the side region is significantly reduced. Accordingly, the first touch lines 221 in the side region have a large adjustment space. Therefore, in the embodiments of the present disclosure, the first touch lines 221 in the side region as a whole are moved towards a side away from the display region AA, thereby making space for the third common signal line 213 and forming a sufficient distance between the first touch lines 221 and the common display signal line.

In some specific embodiments, in the outermost first touch line group Z1 among the M first touch line groups Z1, the first touch lines 221 in the display region AA have a first wire distance h1, and the first touch lines 221 in the side region have a second wire distance h2. The first wire distance h1 is greater than or equal to the second wire distance h2. The “wire distance” or similar expressions may indicate a density of wires, the larger the wire distance, the sparser the wires, and the smaller the wire distance, the denser the wires.

In the embodiments of the present disclosure, the wire distance between the first touch lines 221 in the side region may be reduced, that is, the first wire distance h1 is greater than the second wire distance h2, so that the first touch lines 221 in the side region may be arranged denser to make space for the third common signal line 213 and form a sufficient distance between the first touch lines 221 and the common display signal line. Alternatively, the wire distance between the first touch lines 221 in the side region may be kept unchanged, that is, the first wire distance h1 is made to be equal to the second wire distance h2, and the first touch lines 221 in the side region may be moved rightward as a whole, thereby making space for the third common signal line 213.

Through the above two methods, it is only needed to change the arrangement of the first touch lines 221 in the outermost first touch line group Z1, and the third common signal line 213 and its related wires may remain unchanged, so that the change amplitude is small.

In some specific embodiments, it is also possible to reduce the number of first touch lines 221 in the side region in the outermost first touch line group Z1. In this way, it is also possible to make space for the third common signal line 213.

In some specific embodiments, in the M first touch line groups Z1, except for the outermost first touch line group Z1, the first touch lines 221 in other first touch line groups Z1 have a third wire distance h3, which is equal to the first wire distance h1. For example, in any one of a 2^{nd} first touch line group Z1 to an (M-1)^{th} first touch line group Z1, the first touch lines 221 have the third wire distance h3, so that the first touch lines 221 in the display region AA may be evenly distributed, which may help improve the wire uniformity.

In this example, the first wire distance h1 may be greater than the second wire distance h2 or equal to the second wire distance h2. When the first wire distance h1 is greater than the second wire distance h2, the display substrate may adopt any of the first stacked structure, the second stacked structure and the third stacked structure.

When the first wire distance h1 is equal to the second wire distance h2, the display substrate may adopt the third stacked structure. In this example, the first touch lines 221 in any two of the M first touch line groups Z1 may have the same wire distance, so that each first touch line group Z1 has substantially the same wire arrangement.

In some specific embodiments, in the M first touch line groups Z1, the outermost first touch line group Z1 has a same resistance as other first touch line groups Z1.

In this example, the outermost first touch line group Z1 may refer to a 1^{st} first touch line group Z1 or an M^{th} first touch line group Z1, and other first touch line groups Z1 may refer to the 2^{nd} first touch line group Z1 to the (M-1)^{th} first touch line group Z1. For example, the outermost first touch line group Z1 is identical with other first touch line groups Z1 in terms of the number and line width of the first touch lines 221. Thus, the outermost first touch line group Z1 may have the same resistance as other first touch line groups Z1. For another example, the number of first touch lines 221 in the outermost first touch line group Z1 is less than the number of first touch lines 221 in other first touch line groups Z1, but the line width of the first touch line 221 in the outermost first touch line group Z1 is greater than the line width of the first touch line 221 in other first touch line groups Z1. In this way, the outermost first touch line group Z1 may also have the same resistance as other first touch line groups Z1. The outermost first touch line group Z1 having the same resistance as other first touch line groups Z1 is conducive to the uniformity of the touch detection.

Referring to FIG. 12, in some specific embodiments, the first touch lines 221 and the part of the third common signal line 213 in the side region are arranged in different layers. An orthographic projection of the third common signal line 213 on the base substrate 200 defines a first pattern. In the outermost first touch line group among the M first touch line groups, an orthographic projection of the first touch lines 221 in the display region AA on the base substrate 200 defines a second pattern, and an orthographic projection of the first touch lines 221 in the side region on the base substrate 200 defines a fourth pattern. The first pattern overlaps with the fourth pattern.

In this example, the display substrate adopts the third stacked structure. The part of the third common signal line 213 in the side region may still be located in the original conductive film layer. For example, the part of the third common signal line 213 in the side region is located in the third conductive layer DD3, that is, the part of the third common signal line 213 in the side region is arranged in the same layer as the data lines DL. In this way, the first touch lines 221 may be isolated from the third common signal line 213 by the insulation layer provided between the first conductive layer DD1 and the third conductive layer DD3, and a sufficient distance may be formed between the first touch lines 221 and the third common signal line 213.

In this example, the first touch line group Z1 and the third common signal line 213 have a greater degrees of freedom in wiring. Referring to FIG. 11C, in the side region, the third common signal line 213 may pass through a region where the first touch lines 221 are located. In this case, there is no need to change the third common signal line 213 and its related wires, and the wire distance of the outermost first touch line group Z1 may be consistent with that of other first touch line groups Z1. For example, referring to FIG. 5, the wire distance d2 of the outermost first touch line group Z1 (e.g., the (x+2)^{th} first touch line group Z1 in FIG. 5) is identical with the wire distance (e.g., the third wire distance h3) of other first touch line group Z1 (e.g., the x^{th} first touch line group Z1 in FIG. 5).

FIG. 14 schematically shows a schematic diagram of a connection between the third common signal line and a connecting line according to an embodiment of the present disclosure.

Referring to FIG. 14, it should be noted that, in the side region, the third common signal line 213 may be connected to a common electrode line located in the display region through a connecting line V1 located in the second transparent electrode layer DJ, and then connected to the second electrode of each sub-pixel through the common electrode line. Therefore, in this example, although the first touch lines 221 in the outermost first touch line group Z1 may overlap with the third common signal line 213, the first touch lines 221 still need to avoid a connection region of the third common signal line 213 and the connecting line V 1.

In some specific embodiments, the two side regions include a first side region Q31 and a second side region Q32. With reference to FIG. 5 and FIG. 6, the first side region Q31 is located on the left side of the display region AA, and the second side region Q32 is located on the right side of the display region AA. The display substrate further includes a first common signal line 211, a second common signal line 212 and a touch binding end PAD2 on the base substrate 200, the first common signal line 211 and the second common signal line 212 are located in the peripheral region NA, and the touch binding end PAD2 is located in the binding region Q2. The first common signal line 211 is insulated and spaced apart from the second common signal line 212, and the first common signal line 211 and the second common signal line 212 are respectively connected to the touch binding end PAD2.

For example, with reference to FIG. 5, FIG. 6 and FIG. 9, the touch binding end PAD2 includes a plurality of first sensing terminals F1, a plurality of second sensing terminals F2, a plurality of third sensing terminals F3 and a plurality of fourth sensing terminals F4. The M first touch line groups ZI are electrically connected to the plurality of first sensing terminals F1, and different first touch line groups Z1 are electrically connected to different first sensing terminals F1. The N second touch line groups Z2 are electrically connected to the plurality of second sensing terminals F2, and different second touch line groups Z2 are electrically connected to different second sensing terminals F2. The first common signal line 211 has one end electrically connected to a third sensing terminal F3 and the other end electrically connected to another third sensing terminal F3. The second common signal line 212 has one end electrically connected to a fourth sensing terminal F4 and the other end electrically connected to another fourth sensing terminal F4. Optionally, the plurality of first sensing terminals F1 are located between two adjacent third sensing terminals F3, and the plurality of second sensing terminals F2 are located between two adjacent fourth sensing terminals F4.

Optionally, the display substrate further includes a plurality of first touch leads 231 and a plurality of second touch leads 232. The M first touch line groups Z1 are electrically connected to the touch binding end PAD2 through the plurality of first touch leads 231, and different first touch line groups Z1 are electrically connected to the touch binding end PAD2 through different first touch leads 231. The N second touch line groups Z2 are electrically connected to the touch binding end PAD2 through the plurality of second touch leads 232, and different second touch line groups Z2 are electrically connected to the touch binding end PAD2 through different first touch leads 231. For example, each first touch line group Z1 is connected to one and same first sensing terminal F1 through a first touch lead 231, and each second touch line group Z2 is connected to one and same second sensing terminal F2 through a second touch lead 232.

Exemplarily, after the x^{th} first touch line group Z1 and the (x+2)^{th} first touch line group Z1 are conducted with the touch detection chip, the x^{th} first touch line group Z1, the (x+2)^{th} first touch line group Z1, the first common signal line 211 and corresponding first touch leads 231 jointly enclose to form a first electromagnetic touch coil, where the “corresponding first touch leads 231” refer to the first touch lead 231 connected to the x^{th} first touch line group Z1 and the first touch lead 231 connected to the (x+2)^{th} first touch line group Z1. After a y^{th} second touch line group Z2 and a (y+2)^{th} second touch line group Z2 are conducted with the touch detection chip, the y^{th} second touch line group Z2, the (y+2)^{th} second touch line group Z2, the second common signal line 212 and corresponding second touch leads 232 jointly enclose to form a second electromagnetic touch coil, where the “corresponding second touch leads 232” refer to the second touch lead 232 connected to the y^{th} second touch line group Z2 and the second touch lead 232 connected to the (y+2)^{th} second touch line group Z2.

With reference to FIG. 5, FIG. 6 and FIG. 8, in the binding opposite region Q1, an orthographic projection of the first common signal line 211 on the base substrate 200 is located on a side of an orthographic projection of the second common signal line 212 on the base substrate 200 close to an orthographic projection of the display region AA on the base substrate 200. In the side region, the orthographic projection of the second common signal line 212 on the base substrate 200 is located on a side of the orthographic projection of the first common signal line 211 on the base substrate 200 close to the orthographic projection of the display region AA on the base substrate 200. The first touch line group Z1 is connected to the first common signal line 211 in the binding opposite region Q1, and the second touch line group Z2 is connected to the second common signal line 212 in the first side region Q31.

Optionally, in the binding opposite region Q1, the first common signal line 211 and the second common signal line 212 are arranged in the same layer. For example, in the binding opposite region Q1, the first common signal line 211, the second common signal line 212 and the gate lines GL are arranged in the same layer, so that the first common signal line 211 and the second common signal line 212 may avoid a wiring conflict with the data lines DL, and the number of cross-connection structures provided for solving the wiring conflict may be reduced.

In the binding opposite region Q1, the first common signal line 211 is closer to the display region AA than the second common signal line 212, so that a connection region of the first touch lines 221 and the first common signal line 211 may be provided between the second common signal line 212 and the display region AA, then the first touch lines 221 may be prevented from overlapping with the second common signal line 212, and a crosstalk between the first touch lines 221 and the second common signal line 212 may be reduced.

In the side region, the second common signal line 212 is closer to the display region AA than the first common signal line 211. Accordingly, in the first side region Q31, a connection region of the second touch lines 222 and the second common signal line 212 may be provided between the first common signal line 211 and the display region AA, so that the second touch lines 222 may be prevented from overlapping with the first common signal line 211, and a crosstalk between the second touch lines 222 and the first common signal line 211 may be reduced. In the second side region Q32, a position relationship between the first common signal lines 211 and the second common signal line 212 is consistent with that in the first side region Q31, which is conductive to the wire uniformity.

In some specific embodiments, the peripheral region NA further includes a plurality of corner regions Q4, and at least one corner region Q4 is located between the binding opposite region Q1 and the side region.

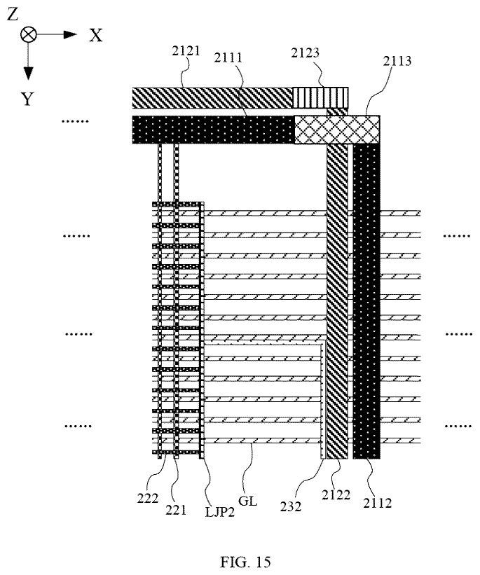

FIG. 15 schematically shows a schematic diagram of a corner region according to an embodiment of the present disclosure.

Referring to FIG. 15, in at least one corner region Q4, the first common signal line 211 includes a first extension portion 2111, a second extension portion 2112 and a first connecting portion 2113 connected between the first extension portion 2111 and the second extension portion 2112, and the second common signal line 212 includes a third extension portion 2121, a fourth extension portion 2122 and a second connecting portion 2123 connected between the third extension portion 2121 and the fourth extension portion 2122. The first extension portion 2111 and the third extension portion 2121 both extend in the second direction X and are arranged in the same layer. The second extension portion 2112 and the fourth extension portion 2122 both extend in the first direction Y and are arranged in the same layer. The first connecting portion 2113 is located in the second transparent electrode layer DJ. The first connecting portion 2113 extends in the second direction X and spans over the fourth extension portion 2122.

Exemplarily, with reference to FIG. 8 and FIG. 14, the peripheral region NA includes four corner regions Q4, where an upper left corner region Q4 and an upper right corner region Q4 are referred to as first corner regions, and lower left corner region Q4 and lower right corner region Q4 are referred to as second corner regions. In each corner region Q4, the first common signal line 211 includes a first extension portion 2111 extending horizontally and a second extension portion 2112 extending vertically, and the second common signal line 212 includes a third extension portion 2121 extending horizontally and a fourth extension portion 2122 extending vertically. The first extension portion 2111 and the third extension portion 2121 may be arranged in the same layer as the gate lines GL, and the second extension portion 2112 and the fourth extension portion 2122 may be arranged in the same layer as the data lines DL. The first connecting portion 2113 overlaps partially with the first extension portion 2111, and the first connecting portion 2113 is connected to the first extension portion 2111 in an overlapping region thereof. The first connecting portion 2113 further overlaps with the second extension portion 2112, and the first connecting portion 2113 is connected to the second extension portion 2112 in an overlapping region thereof. The second connecting portion 2123 overlaps partially with the third extension portion 2121, and the second connecting portion 2123 is connected to the third extension portion 2121 in an overlapping region thereof. The second connecting portion 2123 further overlaps with the fourth extension portion 2122, and the second connecting portion 2123 is connected to the fourth extension portion 2122 in an overlapping region thereof. The second connecting portion 2123 may be located in the second transparent electrode layer DJ.

As described above, in the binding opposite region Q1, the first common signal line 211 is closer to the display region AA than the second common signal line 212, that is, the first common signal line 211 is located on an inner side of the second common signal line 212. In the side region, the second common signal line 212 is closer to the display region AA than the first common signal line 211, that is, the second common signal line 212 is located on an inner side of the first common signal line 211. In the embodiments of the present disclosure, through the above-mentioned connection in the corner region Q4, it is possible to change an internal and external relationships between the first common signal line 211 and the second common signal line 212 while changing an extension direction of the two. In this way, an overlapping area between the first touch lines 221 and the second common signal line 212 (as well as between the second touch lines 222 and the first common signal line 211) is reduced, so that the crosstalk between the first touch lines 221 and the second common signal line 212 (as well as between the second touch lines 222 and the first common signal line 211) may be reduced.

In other specific embodiments, the display substrate further includes a data line DL on the base substrate 200. Exemplarily, the sub-pixel PX includes a first transistor, and the first transistor has a first electrode, a second electrode. One of the first electrode and the second electrode of the first transistor is connected to the data line DL, the other of the first electrode and the second electrode is connected to the pixel electrode in the sub-pixel PX. A gate electrode of the first transistor is connected to the gate line GL. The third common signal line 213 is connected to the second electrode to provide a constant common signal to the second electrode. When a valid level signal is provided on the gate line GL, the first transistor is turned on, and a data signal on the data line DL may be transmitted to the first electrode through the first transistor. In this case, the second electrode and the first electrode of the sub-pixel PX may generate a first electric field according to the common signal and the data signal, and then liquid crystals in the liquid crystal layer are driven by the first electric field to deflect to achieve the display function.

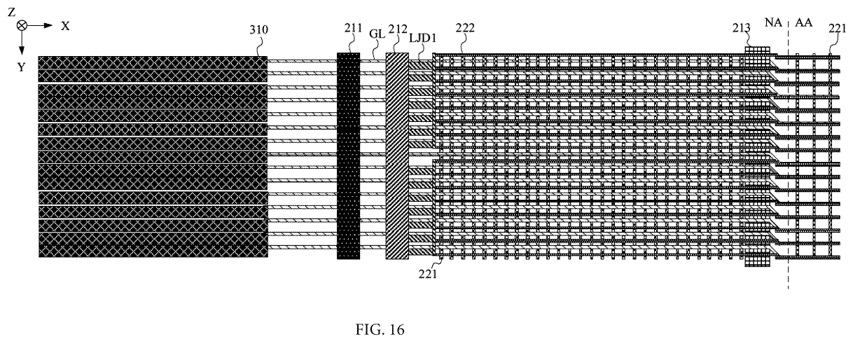

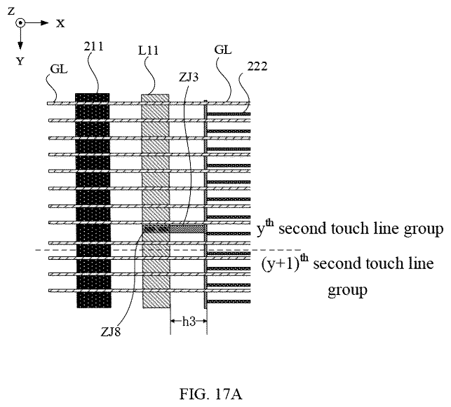

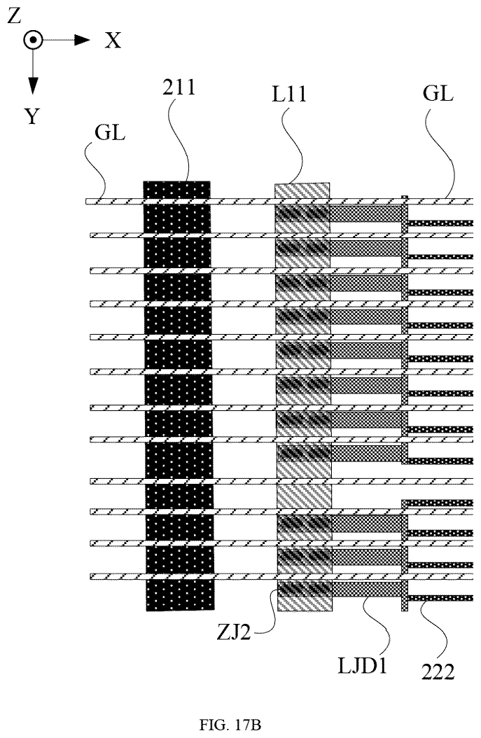

FIG. 16 schematically shows a schematic diagram of the first side region according to an embodiment of the present disclosure. FIG. 17A schematically shows a first schematic diagram of a connection between the second touch line group and the second common signal line according to an embodiment of the present disclosure. In order to show an eighth transfer structure, a first sub-line segment L11 in FIG. 17A is shown as transparent.

With reference to FIG. 5, FIG. 6 and FIG. 8, in the embodiments of the present disclosure, the first common signal line 211 includes a first line segment L1 in the binding opposite region Q1 and a second line segment L2 in the side region, the second common signal line includes a third line segment L3 in the binding opposite region Q1 and a fourth line segment L4 in the side region, and the third common signal line 213 includes a fifth line segment L5 in the binding opposite region Q1 and a sixth line segment L6 in the side region Q3.

With reference to FIG. 6, FIG. 16 and FIG. 17A, the second common signal line 212 includes a first sub-line segment L11 in the first side region Q31, and specifically, the fourth line segment L4 in the first side region Q31 includes a first sub-line segment L11. The first sub-line segment L11 is arranged in the same layer as the data lines, and the second touch lines 222 are arranged in a different layer from the data lines. An orthographic projection of a part of the second touch line group Z2 in the first side region Q31 on the base substrate 200 does not overlap with an orthographic projection of the first sub-line segment L11 on the base substrate 200, and a plurality of second touch line groups Z2 are connected to the first sub-line segment L11 through one and same third transfer structure ZJ3.

In the embodiments of the present disclosure, the first sub-line segment L11 is arranged in the same layer as the data lines DL to avoid a wiring conflict with the gate lines GL. The second touch lines 222 may be arranged in the same layer as the gate lines GL, or the second touch lines 222 may be located separately in the second conductive layer DD2. In the embodiments of the present disclosure, at least two second touch line groups Z2 are connected together through the third transfer structure ZJ3 and then extend to a position of the first sub-line segment L11. Optionally, the third transfer structure ZJ3 is arranged in a different layer from the gate lines GL to avoid short-circuit with the gate lines GL. For example, the display substrate adopts the second stacked structure, in which the second touch lines 222 and the third transfer structure ZJ3 are both located in the second conductive layer DD2, and the gate lines GL are located in the fourth conductive layer DD4.

Optionally, the third transfer structure ZJ3 may be connected to the first sub-line segment L11 through an eighth transfer structure ZJ8 after extending to the position of the first sub-line segment L11. Exemplarily, the eighth transfer structure ZJ8 is located in the second transparent electrode layer DJ.

In some specific embodiments, in the second direction X, a distance h4 between the second touch line group Z2 and the second common signal line 212 is less than or equal to 3500 μm. For example, the distance h4 between the second touch line group Z2 and the second common signal line 212 is less than or equal to 3000 μm. In this way, the second touch line group Z2 may be as close as possible to the second common signal line 212, so that a coverage area of the second touch line group Z2 may be increased.

FIG. 17B schematically shows a second schematic diagram of a connection between the second touch line group and the second common signal line according to an embodiment of the present disclosure. In order to show a second transfer structure, a first sub-line segment L11 in FIG. 17B is shown as transparent.

Referring to FIG. 17B, in some other specific embodiments, the display substrate further includes a data line DL provided on the base substrate 200, the second common signal line 212 includes a first sub-line segment L11 located in the first side region Q31, the first sub-line segment L11 is arranged in the same layer as the data line GL, and the second touch lines 222 are arranged in a different layer from the data line GL. An orthographic projection of a part of the second touch line group Z2 in the first side region Q31 on the base substrate 200 overlaps with an orthographic projection of the first sub-line segment L11 on the base substrate 200, and the second touch line group Z2 is connected to the first sub-line segment L11 through a second transfer structure ZJ2 in an overlapping region thereof, where the second transfer structure ZJ2 is located in the second transparent electrode layer DJ. In an example, the second transfer structures ZJ2 connected to different second touch line groups Z2 are spaced apart from each other. For example, the second transfer structures ZJ2 on the display substrate are independent block structures. In another example, the second transfer structures ZJ2 connected to different second touch line groups Z2 are formed as an integrated structure. For example, the second transfer structures ZJ2 on the display substrate are connected to each other to extend continuously from an upper end of the first side region Q31 (i.e., an end close to the binding opposite region Q1) to a lower end of the first side region Q31 (i.e., an end close to the binding region Q2).

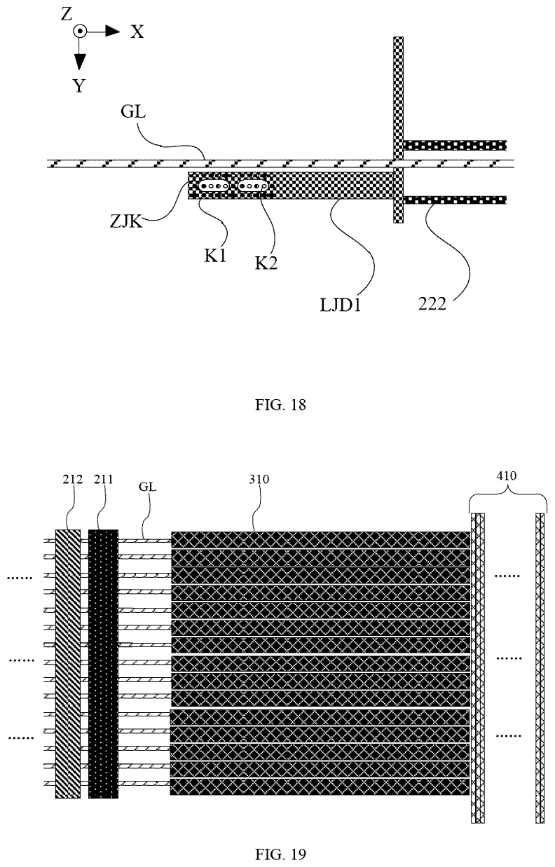

FIG. 18 schematically shows a schematic diagram of a first via hole and a second via hole according to an embodiment of the present disclosure.

Exemplarily, referring to FIG. 18, the second touch line group Z2 includes a first connection end portion LJD1, which extends to the position of the first sub-line segment L11 and overlaps with the first sub-line segment L11. In an overlapping region thereof, the first connection end portion LJD1 may be connected to the second transfer structure ZJ2 through a plurality of first via holes K1. The first connection end portion LJD1 is provided with a transfer opening ZJK, and the first sub-line segment L11 is connected to the second transfer structure ZJ2 in the transfer opening ZJK. Optionally, the plurality of first via holes K1 may enclose to form a ring. For example, the plurality of first via holes K1 may surround the transfer opening ZJK, so that the first connection end portion LJD1 is connected to the second transfer structure ZJ2 in a periphery of the transfer opening ZJK. Optionally, the transfer opening ZJK is filled with a first insulation structure, which may be one or more insulation layers between the second conductive layer DD2 and the second transparent electrode layer DJ. The first insulation structure is provided with a plurality of second via holes K2 arranged in the second direction X. The second transfer structure ZJ2 may be connected to the first sub-line segment L11 through the plurality of second via holes K2.

Optionally, in the overlapping region of the first connection end portion LJD1 and the first sub-line segment L11, the first connection end portion LJD1 may also be directly connected to the first sub-line segment L11.

In this example, the distance between the second touch line group Z2 and the second common signal line 212 is further reduced, so that the coverage area of the second touch line group Z2 is further increased, and a space utilization is improved.

FIG. 19 schematically shows a first schematic diagram of a position relationship between a shift register unit and the first common signal line according to an embodiment of the present disclosure.

Referring to FIG. 19, in some specific embodiments, the display substrate further includes a data line, a gate line and a shift register unit 310 on the base substrate, where the shift register unit 310 is located in the side region. An orthographic projection of the shift register unit 310 on the base substrate 200 is located on a side of an orthographic projection of the first common signal line 211 on the base substrate 200 away from an orthographic projection of the display region AA on the base substrate 200. A first signal line 410 is provided on the base substrate 200 and connected to the shift register unit 310, and the first signal line 410 is arranged in the same layer as at least one of the data line DL and the gate line GL. For example, the first signal line 410 may include but not be limited to a clock signal line, a first voltage signal line, and a second voltage signal line. In the side region, an orthographic projection of the first signal line 410 on the base substrate 200 is located on a side of the orthographic projection of the shift register unit 310 on the base substrate 200 away from the orthographic projection of the first common signal line 211 on the base substrate 200.

In the embodiments of the present disclosure, one of the first voltage signal line and the second voltage signal line is used to provide a constant low level signal, and the other is used to provide a constant high level signal. Exemplarily, in the side region, the first touch line group Z1 (the first one or the M^{th} one), the second common signal line 212 and the first common signal line 211 are arranged sequentially in a direction away from the display region AA. The shift register unit 310 is located on a side of the first common signal line 211 away from the display region AA, and the clock signal line, the first voltage signal line and the second voltage signal line are located on a side of the shift register unit 310 away from the display region AA. In this way, the clock signal line, the first voltage signal line and the second voltage signal line may be arranged away from a region where the touch wires are located, so as to prevent wire crossing and avoid crosstalk.

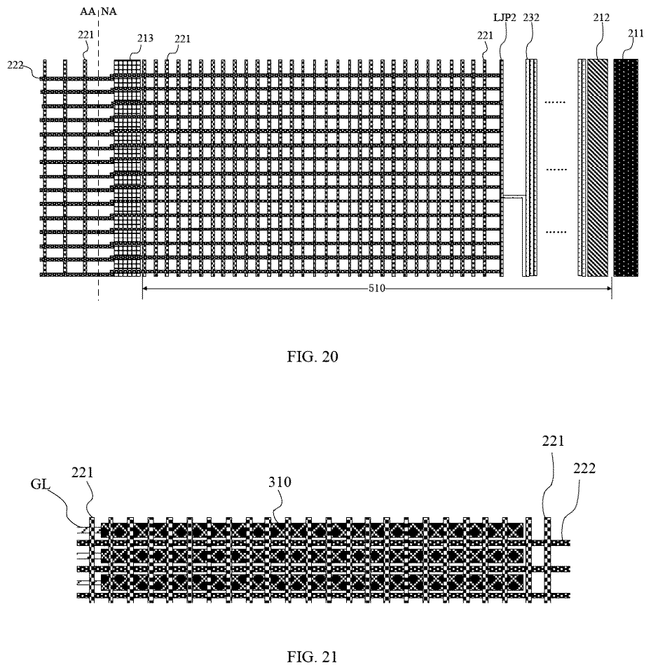

FIG. 20 schematically shows a second schematic diagram of a position relationship between a shift register unit and the first common signal line according to an embodiment of the present disclosure. It should be noted that for clarity, the shift register unit 310 is not shown in FIG. 20, and only a region 510 where the shift register unit 310 may be provided is shown with a dashed line.

Referring to FIG. 20, in some specific embodiments, the display substrate further includes a data line DL, a gate line GL and a shift register unit 310 on the base substrate 200, where the shift register unit 310 is located in the side region. An orthographic projection of the shift register unit 310 on the base substrate 200 is located on a side of the orthographic projection of the second common signal line 212 on the base substrate 200 close to the orthographic projection of the display region AA on the base substrate 200, and the second touch lines 222 are arranged in a different layer from the data line DL and the gate line GL. An orthographic projection of at least one second touch line 222 on the base substrate 200 overlaps with the orthographic projection of the shift register unit 310 on the base substrate 200.

In this example, the display substrate adopts the second stacked structure or the third stacked structure. In the embodiments of the present disclosure, in the region where the shift register unit 310 is located, a large number of wires and conductive structures are arranged in the same layer as the gate line GL, and the second touch lines 222 are separately located in the second conductive layer DD2, so that the second touch lines 222 may be prevented from being short-circuited with the wires and conductive structures arranged in the same layer as the gate line GL in the region where the shift register units 310 are located.

Optionally, the remaining wires and conductive structures in the region where the shift register units 310 are located are arranged in a different layer from the second touch lines 222. For example, in the second stacked structure, these wires and conductive structures may be located in the first conductive layer DD1, while in the third stacked structure, these wires and conductive structures may be located in the third conductive layer DD3. Certainly, the above is merely an exemplary illustration, and these wires and conductive structures may be located in any suitable conductive film layer, for example in the second transparent electrode layer DJ.

It should be noted that, in the region where the shift register unit 310 is located, a large number of wires and conductive structures are arranged in the same layer as the gate line GL, and a gap formed between these wires and conductive structures is extremely small. If the second touch lines 222 are arranged in the same layer as the gate line GL, the second touch lines 222 are very easy to be short-circuited with these wires and conductive structures. Therefore, if the first stacked structure is to be adopted, that is, if the second touch lines 222 are arranged in the same layer as the gate line GL, the second touch lines 222 need to avoid the shift register unit 310. For example, the second touch lines 222 may be located on a side of the shift register unit 310 close to the display region AA.

In some specific embodiments, the orthographic projection of the first touch lines 221 on the base substrate 200 does not overlap with the orthographic projection of the shift register units 310 on the base substrate 200.

In this example, the display substrate adopts the second stacked structure or the third stacked structure. In the region where the shift register unit 310 is located, a large number of wires and conductive structures are arranged in the same layer as the data line DL. For example, the data line DL and a first electrode of a second transistor are both located in the first conductive layer DD1 (or the third conductive layer DD3). It should be noted that the gap between these wires and conductive structures is extremely small, and if the first touch lines 221 are arranged in the same layer as the data line DL, the first touch lines 221 are very easy to be short-circuited with these wires and conductive structures. Therefore, if the second stacked structure is to be adopted, that is, if the second touch lines 222 are arranged in the same layer as the gate line GL, the second touch lines 222 need to avoid the shift register unit 310. For example, in the outermost first touch line group Z1, the first touch lines 221 in the side region may be further divided into two parts, one part is located on a side of the shift register unit 310 close to the display region AA, and the other part is located on a side of the shift register units 310 away from the display region AA. Alternatively, the first touch lines 221 may be arranged only on a side of the shift register unit 310 close to the display region AA.

In some specific embodiments, the display substrate further includes a data line DL, a gate line GL and a shift register unit 310 on the base substrate 200, where the shift register unit 310 is located in the side region. An orthographic projection of the shift register unit 310 on the base substrate 200 is located on a side of the orthographic projection of the second common signal line 212 on the base substrate 200 close to the orthographic projection of the display region AA on the base substrate 200. The first touch lines 221 and the second touch lines 222 are arranged in different layers from the data line DL and the gate line GL. An orthographic projection of at least one second touch line 222 on the base substrate 200 overlaps with the orthographic projection of the shift register unit 310 on the base substrate 200, and an orthographic projection of at least one first touch line 221 on the base substrate 200 overlaps with the orthographic projection of the shift register unit 310 on the base substrate 200.

In this example, the display substrate adopts the third stacked structure. For example, a part of the wires and conductive structures in the region where the shift register unit 310 is located, is located in the fourth conductive layer DD4, and the other part is located in the third conductive layer DD3. The first touch lines 221 and the second touch lines 222 are located in the first conductive layer DD1 and the second conductive layer DD2 respectively. In this way, the first touch lines 221 and the second touch lines 222 may not have wire conflict with the wires and the conductive structures in the region where the shift register unit 310 is located. In this example, the first touch lines 221 and the second touch lines 222 have greater degrees of freedom in wiring, they do not need to avoid the shift register unit 310 and may overlap with the shift register unit 310, so that the space utilization may be improved. Moreover, compared with the solution that the shift register unit 310 is arranged on an outer side of a region where the touch wires are located, this method may reduce a width of the peripheral region NA to achieve a narrow bezel, or the first touch lines 221 and the second touch lines 222 may further extend towards a boundary of the display substrate, so as to further increase the touch detection area.

Certainly, the above is merely an exemplary illustration, and the wires and conductive structures in the region where the shift register unit 310 is located may be located in any suitable conductive film layer, for example, in the second transparent electrode layer DJ.

FIG. 21 schematically shows a schematic diagram of providing the second common signal line in a first gap according to an embodiment of the present disclosure.

Referring to FIG. 21, in some specific embodiments, the display substrate further includes a plurality of shift register units 310 provided on the base substrate 200 and located in the side region, and an orthographic projection of the shift register units 310 on the base substrate 200 is located on a side of the orthographic projection of the second common signal line 212 on the base substrate 200 close to the orthographic projection of the display region AA on the base substrate 200. The plurality of shift register units 310 are arranged in the first direction Y. A first gap is formed between two adjacent shift register units 310, and an orthographic projection of at least one second touch line 222 on the base substrate 200 passes through an orthographic projection of the first gap on the base substrate 200. For example, in the embodiments of the present disclosure, each second touch line 222 passes through a first gap, and each gap is passed by only one second touch line 222.

In this example, the display substrate may adopt the first stacked structure, the second stacked structure or the third stacked structure. When the display substrate adopts the first stacked structure, the second touch line 222 passes through the first gap and may not be short-circuited with the wires or conductive structures in the region where the shift register unit 310 is located. When the display substrate adopts the second stacked structure or the third stacked structure, the second touch line 222 passes through the first gap so that a larger distance may be formed between the second touch line 222 and the shift register unit 310, which may help reduce crosstalk.

Referring to FIG. 8, in some specific embodiments, the orthographic projection of the M first touch line groups Z1 on the base substrate 200 defines a seventh pattern, and the orthographic projection of the N second touch line groups Z2 on the base substrate 200 defines an eighth pattern.

Exemplarily, the seventh pattern may refer to a pattern enclosed by an orthographic projection of an outermost edge of the M first touch line groups Z1 on the base substrate 200. The eighth pattern may refer to a pattern enclosed by an orthographic projection of an outermost edge of the N second touch line groups Z2 on the base substrate 200.

The orthographic projection of the first common signal line 211 on the base substrate 200 at least partially surrounds the seventh pattern. The orthographic projection of the second common signal line 212 on the base substrate 200 at least partially surrounds the eighth pattern.

The first common signal line 211 extends continuously in the first side region Q31, the binding opposite region Q1 and the second side region Q32, thereby surrounding a periphery of the M first touch line groups Z1. The M first touch line groups Z1 are connected to the first common signal line 211 in the binding opposite region Q1. The first common signal line 211 extends from the first side region Q31 and the second side region Q32 to the binding region Q2 respectively, and in the binding region Q2, one end of the first common signal line 211 is electrically connected to a third sensing terminal F3, and the other end is electrically connected to another third sensing terminal F3. In this way, the first common signal line 211 may be multiplexed as a set of windings of the first electromagnetic touch coil. The second common signal line 212 extends continuously in the first side region Q31, the binding opposite region Q1 and the second side region Q32, thereby surrounding a periphery of the N second touch line groups Z2. The N second touch line groups Z2 are connected to the second common signal line 212 in the first side region Q31. The second common signal line 212 extends from the first side region Q31 and the second side region Q32 to the binding region Q2 respectively, and in the binding region Q2, one end of the second common signal line 212 is electrically connected to a fourth sensing terminal F4, and the other end is electrically connected to another fourth sensing terminal F4. In this way, the second common signal line 212 may be multiplexed as a set of windings of the second electromagnetic touch coil.

The orthographic projection of the third common signal line 213 on the base substrate 200 at least partially surrounds the orthographic projection of the display region AA on the base substrate 200, and either of the orthographic projection of the first common signal line 211 on the base substrate and the orthographic projection of the second common signal line 212 on the base substrate 200 is located on a side of the orthographic projection of the third common signal line 213 on the base substrate 200 away from the orthographic projection of the display region AA on the base substrate 200.

In this embodiment, the first touch lines 221 avoid the third common signal line 213 to improve the crosstalk. In this embodiment, in the two side regions, the third common signal line 213 may be located on an inner side of common touch signal lines (i.e., the first common signal line 211 and the second common signal line 212). In this embodiment, in the binding opposite region Q1 and the binding region Q2, the third common signal line 213 is also located on an inner side of the common touch signal lines. In this way, the position relationship between the common touch signal lines and the third common signal line 213 is consistent on the entire display substrate, so that the wiring uniformity of the common touch signal lines and the third common signal line 213 may be ensured.

In some other specific embodiments, the orthographic projection of the M first touch line groups Z1 on the base substrate 200 defines a seventh pattern, and the orthographic projection of the first common signal line 211 on the base substrate 200 at least partially surrounds the seventh pattern. The orthographic projection of the N second touch line groups Z2 on the base substrate 200 defines an eighth pattern, and the orthographic projection of the second common signal line 212 on the base substrate 200 at least partially surrounds the eighth pattern. The orthographic projection of the third common signal line 213 on the base substrate 200 at least partially surrounds the orthographic projection of the display region AA on the base substrate 200. In at least one of the binding region Q2 and the binding opposite region Q1, either of the orthographic projection of the first common signal line 211 on the base substrate 200 and the orthographic projection of the second common signal line 212 on the base substrate 200 is located on a side of the orthographic projection of the third common signal line 213 on the base substrate 200 close to the orthographic projection of the display region AA on the base substrate 200. In the side region, either of the orthographic projection of the first common signal line 211 on the base substrate 200 and the orthographic projection of the second common signal line 212 on the base substrate is located on a side of the orthographic projection of the third common signal line 213 on the base substrate 200 away from the orthographic projection of the display region AA on the base substrate 200.

Different from the foregoing embodiments, in this embodiment, in the two side regions, the third common signal line 213 is still located on an inner side of the common touch signal lines, while in the binding opposite region Q1 and the binding region Q2, the third common signal line 213 is located on an outer side of the common touch signal lines. In this way, the wiring flexibility may be increased. Optionally, an internal and external relationship between the third common signal line 213 and the common touch signal lines may be exchanged in the corner region Q4.

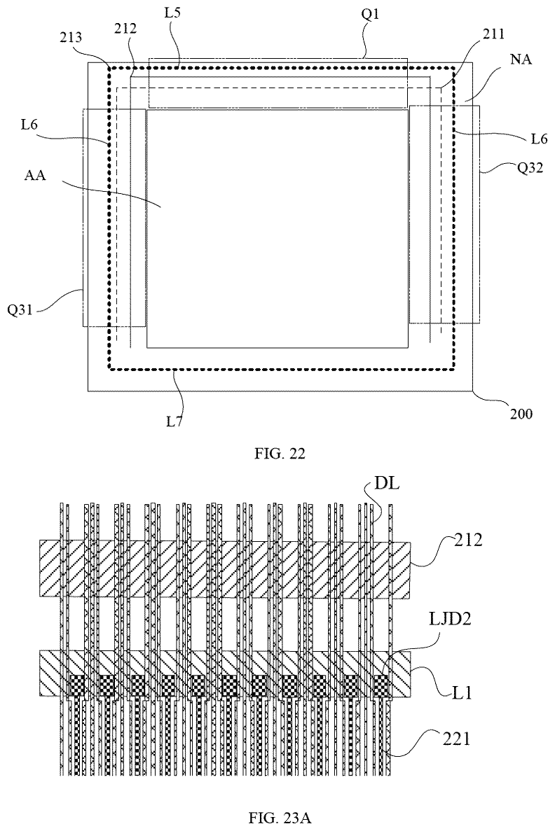

FIG. 22 schematically shows a second schematic diagram of the third common signal line according to an embodiment of the present disclosure.

Referring to FIG. 22, in some other specific embodiments, the orthographic projection of the M first touch line groups Z1 on the base substrate 200 defines a seventh pattern, and the orthographic projection of the first common signal line 211 on the base substrate 200 at least partially surrounds the seventh pattern. The orthographic projection of the N second touch line groups Z2 on the base substrate 200 defines an eighth pattern, and the orthographic projection of the second common signal line 212 on the base substrate 200 at least partially surrounds the eighth pattern. The orthographic projection of the third common signal line 213 on the base substrate 200 at least partially surrounds the orthographic projection of the display region AA on the base substrate 200, and either of the orthographic projection of the first common signal line 211 on the base substrate 200 and the orthographic projection of the second common signal line 212 on the base substrate 200 is located on a side of the orthographic projection of the third common signal line 213 on the base substrate 200 close to the orthographic projection of the display region AA on the base substrate 200.

Different from the foregoing embodiments, in this embodiment, the third common signal line 213 avoids the first touch lines 221 to improve the crosstalk. In this embodiment, in the two side regions, the third common signal line 213 is located on a side of the first touch line group Z1 away from the display region AA, and further, the third common signal line 213 is located on a side of the common touch signal lines away from the display region AA, that is, the third common signal line 213 is located on an outer side of the common touch signal lines, so that the third common signal line 213 is away from a region where the whole touch wires are located. In this embodiment, in the binding opposite region Q1 and the binding region Q2, the third common signal line 213 is also located on an outer side of the common touch signal line. In this way, the position relationship between the common touch signal lines and the third common signal line 213 is consistent on the entire display substrate, so that the wiring uniformity of the common touch signal line and the third common signal line 213 may be ensured.

In some other specific embodiments, the orthographic projection of the M first touch line groups Z1 on the base substrate 200 defines a seventh pattern, and the orthographic projection of the first common signal line 211 on the base substrate 200 at least partially surrounds the seventh pattern. The orthographic projection of the N second touch line groups Z2 on the base substrate 200 defines an eighth pattern, and the orthographic projection of the second common signal line 212 on the base substrate 200 at least partially surrounds the eighth pattern. The orthographic projection of the third common signal line 213 on the base substrate 200 at least partially surrounds the orthographic projection of the display region AA on the base substrate 200. In at least one of the binding region Q2 and the binding opposite region Q1, either of the orthographic projection of the first common signal line 211 on the base substrate 200 and the orthographic projection of the second common signal line 212 on the base substrate 200 is located on a side of the orthographic projection of the third common signal line 213 on the base substrate 200 away from the orthographic projection of the display region AA on the base substrate 200. In the side region, either of the orthographic projection of the first common signal line 211 on the base substrate 200 and the orthographic projection of the second common signal line 212 on the base substrate 200 is located on a side of the orthographic projection of the third common signal line 213 on the base substrate 200 close to the orthographic projection of the display region AA on the base substrate 200.

Different from the foregoing embodiments, in this embodiment, in the two side regions, the third common signal line 213 is still located on an outer side of the common touch signal lines, while in the binding opposite region Q1 and the binding region Q2, the third common signal line 213 is located on an inner side of the common touch signal lines. In this way, the wiring flexibility may be increased. Optionally, the internal and external relationship between the third common signal line 213 and the common touch signal lines may be exchanged in the corner region Q4.

Optionally, in the foregoing embodiments, the internal and external relationship between the first common signal line 211 and the second common signal line 212 may be determined according to actual needs. For example, the first common signal line 211 may be located on an outer side of the second common signal line 212. Alternatively, the second common signal line 212 may be located on an outer side of the first common signal line 211. Alternatively, as described above, in the binding opposite region Q1, the second common signal line 212 is located on an outer side of the first common signal line 211, and in the two side regions, the first common signal line 211 may be located on an outer side of the second common signal line 212.

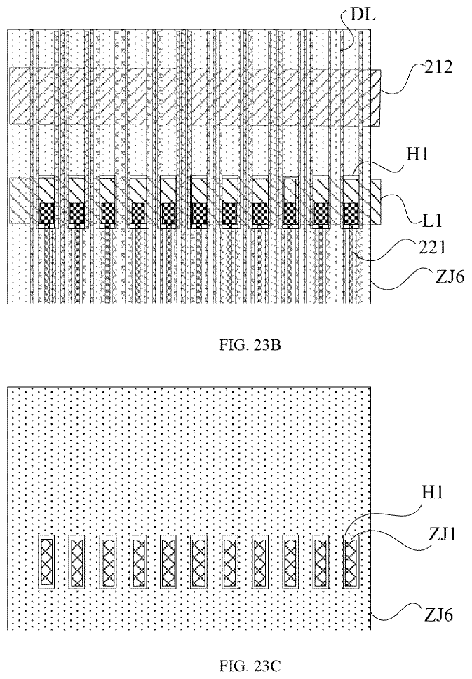

FIG. 23A to FIG. 23C schematically show schematic diagrams of a connection between the first touch line groups and the first common signal line according to an embodiment of the present disclosure.

With reference to FIG. 8 and FIG. 23A to FIG. 23C, in some specific embodiments, the display substrate further includes a gate line GL provided on the base substrate 200 and a common electrode line (not shown) provided on the base substrate 200 and located in the display region AA. The third common signal line 213 includes a fifth line segment L5 in the binding opposite region Q1, and the fifth line segment L5 may be arranged in the same layer as the gate line GL, thereby avoiding short-circuit with a data line DL. The fifth line segment L5 is connected to the common electrode line through a sixth transfer structure ZJ6, and the common electrode line is connected to the second electrode in the sub-pixel PX. Exemplarily, the common electrode line in the display region AA may extend in the second direction X, and the common electrode line may be connected to the second electrode of the plurality of sub-pixels PX (the second electrode may be a common electrode, for example), so as to provide a constant common display signal to the second electrode of the plurality of sub-pixels PX simultaneously.

The first common signal line 211 includes a first line segment L1 in the binding opposite region Q1, the first line segment L1 is arranged in the same layer as the gate line GL, and the first touch lines 221 are arranged in a different layer from the gate line GL. The sixth transfer structure ZJ6 is located in the second transparent electrode layer DJ, and the sixth transfer structure ZJ6 is provided with a first opening H1. An orthographic projection of a part of the first touch line group Z1 in the binding opposite region Q1 on the base substrate 200 overlaps with an orthographic projection the first line segment L1 on the base substrate 200 to, and in an overlapping region thereof, the first touch line group Z1 is connected to the first line segment L1 through a first transfer structure ZJ1 located in the second transparent electrode layer DJ. An orthographic projection of the first transfer structure ZJ1 on the base substrate 200 falls within an orthographic projection of the first opening H1 on the base substrate 200.

Exemplarily, the first line segment L1 may be arranged in the same layer as the gate line GL to avoid a wiring conflict with the data line DL. The first line segment L1 is arranged in a different layer from the first touch lines 221. In the binding opposite region Q1, each first touch line 221 in the first touch line group Z1 extends in a direction away from the display region AA to the position of the first line segment L1, and overlaps with a part of the first transfer structure ZJ1 and the first line segment L1. In an overlapping region thereof, the first touch lines 221 are connected to the first transfer structure ZJ1 through a plurality of third via holes. Optionally, in the overlapping region, the first touch lines 221 may also be directly connected to the first line segment L1 through a plurality of fourth via holes. The other part of the first transfer structure ZJ1 overlaps with the first line segment L1 but does not overlap with the first touch lines 221, and this part of the first transfer structure ZJ1 is connected to the first line segment L1 through a plurality of fifth via holes.

Exemplarily, the sixth transfer structure ZJ6 and the first line segment L1 extend in the second direction X, the sixth transfer structure ZJ6 at least partially overlaps with the first line segment L1, and the sixth transfer structure ZJ6 is provided with a first opening H1 in an overlapping region thereof. Optionally, the first transfer structure ZJ1 is synchronously formed with the sixth transfer structure ZJ6, the first transfer structure ZJ1 is located in the first opening H1 of the sixth transfer structure ZJ6, and the sixth transfer structure ZJ6 is insulated and spaced apart from the first transfer structure ZJ1. For example, in the first opening H1, a second distance is formed between the first transfer structure ZJ1 and the sixth transfer structure ZJ6, and the second distance includes a minimum exposure distance that may ensure an insulation and separation between the first transfer structure ZJ1 and the sixth transfer structure ZJ6.

Optionally, the first opening H1 is filled with a second insulation structure, and the second insulation structure may insulate and separate the first transfer structure ZJ1 from the sixth transfer structure ZJ6. The second insulation structure may be located in one or more insulation film layers on a side of the second transparent electrode layer DJ away from the base substrate 200.

In this way, a transfer connection between the first touch line group Z1 and the first common signal line 211 may be achieved through the first transfer structure ZJ1. Furthermore, in the embodiments of the present disclosure, the first opening H1 is provided on the sixth transfer structure ZJ6 to make space for the first transfer structure ZJ1, so that the position of the sixth transfer structure ZJ6 in the binding opposite region Q1 may remain unchanged.

Optionally, the first touch line 221 includes a second connection end portion LJD2, and an orthographic projection of the second connection end portion LJD2 on the base substrate 200 overlaps with the orthographic projection of the first transfer structure ZJ1 on the base substrate 200. The second connection end portion LJD2 is thicker than the part of the first touch line 221 in the display region AA, which helps the connection between the first touch lines 221 and the first transfer structure ZJ1. Exemplarily, for the data lines DL on left and right sides of the first touch line 221, these data lines DL extend towards a side away from the display region AA, and in the binding opposite region Q1, these data lines DL may be electrically connected to a structure such as an antistatic unit. At least part of these data lines DL are bent in a direction away from the second connection end portion LJD2 when they are getting close to the second connection end portion LJD2, so as to prevent short-circuit between the data lines DL and the second connection end portion LJD2.

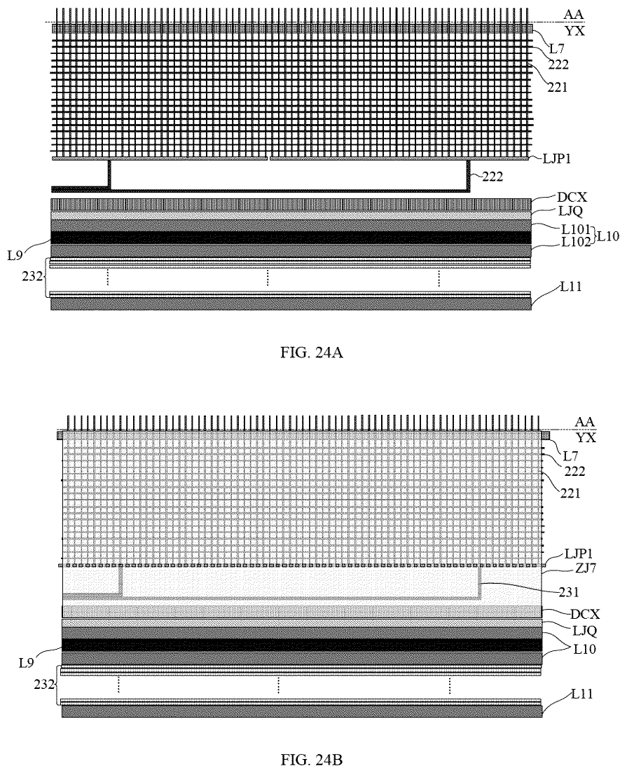

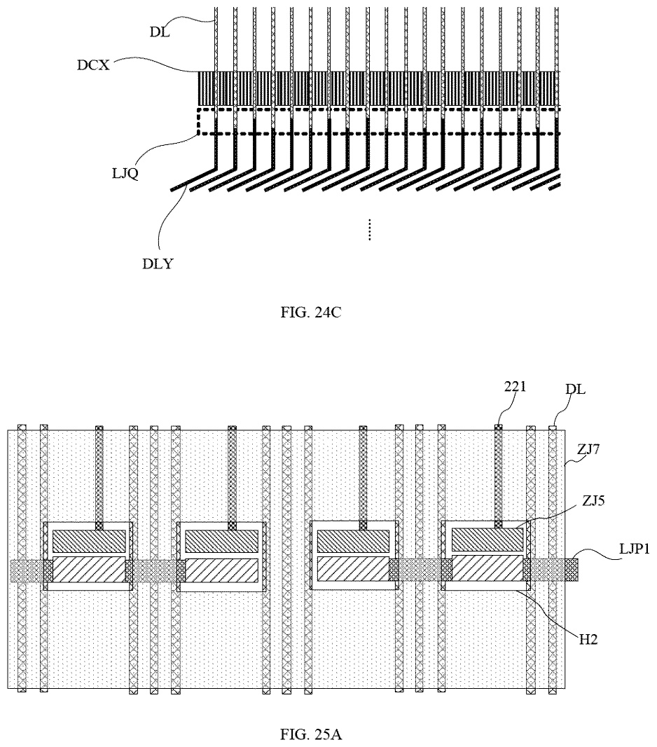

FIG. 24A and FIG. 24B schematically show schematic diagrams of a lead region according to an embodiment of the present disclosure.

With reference to FIG. 24A and FIG. 24B, in some specific embodiments, the display substrate further includes a data line DL and a gate line GL on the base substrate 200. The first common signal line 211 includes a first line segment L1 in the binding opposite region Q1. The first line segment L1 is arranged in the same layer as the first touch lines 221, and in a different layer from the data line DL and the gate line GL. In the binding opposite region Q1, the first touch line group Z1 is directly connected to the first line segment L1.

In the embodiments of the present disclosure, the display substrate may adopt the third stacked structure. In this embodiment, the first touch lines 221 are arranged in the same layer as the first line segment L1, so that a transfer connection between the first touch lines 221 and the first line segment L1 is not required, then the first touch lines 221 may be directly connected to the first line segment L1, and the step of providing the first opening H1 on the sixth transfer structure ZJ6 may be omitted.

In some specific embodiments, the peripheral region NA further includes a lead region YX between the display region AA and the binding region Q2, and the display substrate further includes a data line DL, a second common display signal line DCX and a first touch lead 231 on the base substrate 200.

The third common signal line 213 includes a seventh line segment L7 in the lead region YX, and the seventh line segment L7 extends in substantially the same direction as the second common display signal line DCX. For example, the seventh line segment L7 and the second common display signal line DCX both extend in the second direction X. An orthographic projection of the seventh line segment L7 on the base substrate 200 is located on a side of an orthographic projection of the second common display signal line DCX on the base substrate 200 close to the display region AA. The seventh line segment L7 is connected to the second common display signal line DCX through a seventh transfer structure ZJ7 located in the second transparent electrode layer DJ. In other words, the third common signal line 213 may refer to a wire at a proximal end of the display region AA, and the second common display signal line DCX may refer to a wire at a distal end of the display region AA.

In the lead region YX, the first touch lines 221 are connected to the touch binding end PAD2 through first touch leads 231. The first touch lines 221 are arranged in the same layer as the data line DL, and the first touch leads 231 are arranged in a different layer from the data line DL.

Exemplarily, the seventh line segment L7 may be arranged in the same layer as the gate line GL, thus avoiding short-circuit the data lines DL. The first touch leads 231 may be located in the second conductive layer DD2. The first touch line groups Z1 are connected to the first touch leads 231 in one-to-one correspondence. For example, the first touch lines 221 in each first touch line group Z1 are electrically connected to one and same first sensing terminal F1 in the touch binding end PAD2 through one and same first touch lead 231.

With reference to FIG. 5, FIG. 9, FIG. 24A and FIG. 24B, a part of first touch leads 231 extend toward the right side after being connected to the first touch line groups Z1, and the other part of first touch leads 231 extend toward the left side after being connected to the first touch line groups Z1. All the first touch leads 231 finally converge to an upper side of the touch binding end PAD2 and are connected to the corresponding first sensing terminals F1 on the touch binding end PAD2. Exemplarily, the plurality of first touch leads 231 extending toward the right side are parallel to each other, and the plurality of first touch leads 231 extending toward the left side are parallel to each other.

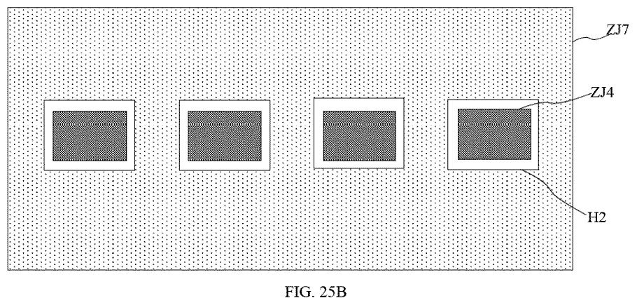

FIG. 25A and FIG. 25B schematically show schematic diagrams of a connection between the first touch line and the first touch lead according to an embodiment of the present disclosure.

With reference to FIG. 24A to FIG. 25B, in the embodiments of the present disclosure, a second opening H2 is provided on the seventh transfer structure ZJ7, and the first touch line 221 is connected to the first touch lead 231 through a fourth transfer structure ZJ4 located in the second transparent electrode layer DJ. An orthographic projection of the fourth transfer structure ZJ4 on the base substrate 200 falls within an orthographic projection of the second opening H2 on the base substrate 200.

Exemplarily, with reference to FIG. 24A to FIG. 24C, the first touch lines 221 in one and same first touch line group Z1 are electrically connected to one and same first touch lead 231 through one and same first connection pad LJP1, and the first connection pad LJP1 extends in the second direction X. In the lead region YX, each first touch line 221 in the first touch line group Z1 extends in a direction away from the display region AA to a position of the fourth transfer structure ZJ4, and overlaps with the fourth transfer structure ZJ4. In an overlapping region thereof, the first touch line 221 is connected to a part of the fourth transfer structure ZJ4 through a plurality of sixth via holes. The other part of the fourth transfer structure ZJ4 overlaps with the first connection pad LPJ1 extending in the second direction X but does not overlap with the first touch line 221, and this portion of the fourth transfer structure ZJ4 is connected to the first connection pad LPJ1 through a plurality of seventh via holes and is then connected to the first touch lead 231 through the first connection pad LPJ1. Optionally, the first connection pad LPJ1 is arranged in the same layer as the first touch lead 231, so that structures such as via holes for transfer connection between the two may be omitted.

Exemplarily, with reference to FIG. 10 and FIG. 11A, the second touch lines 222 in one and same second touch line group Z2 are electrically connected to one and same second touch lead 232 through one and same second connection pad LJP2, and the second connection pad LJP2 extends in the first direction Y. Optionally, the second touch lines 222, the first connection pad LPJ1 and the first touch lead 231 may be arranged in the same layer, so that structures such as via holes for transfer connection between the three may be omitted.

In the embodiments of the present disclosure, the seventh transfer structure ZJ7 extends in the second direction X, and the first touch lead 231 includes a part connected to the first touch line group Z1 and a part extending toward the touch binding end PAD2. The part of the first touch lead 231 connected to the first touch line group Z1 extends in the second direction X and overlaps with the seventh transfer structure ZJ7. In an overlapping region thereof, a second opening H2 is provided on the seventh transfer structure ZJ7. The fourth transfer structure ZJ4 and the seventh transfer structure ZJ7 are synchronously formed through a same patterning process. The fourth transfer structure ZJ4 is located in the second opening H2 on the seventh transfer structure ZJ7, and is insulated and separated from the seventh transfer structure ZJ7. For example, in the second opening H2, a third distance is formed between the fourth transfer structure ZJ4 and the seventh transfer structure ZJ7, and the third distance includes a minimum exposure distance that ensures an insulation and separation between the fourth transfer structure ZJ4 and the seventh transfer structure ZJ7.

Optionally, the second opening H2 is filled with a third insulation structure, and the third insulation structure may insulate and separate the fourth transfer structure ZJ4 from the seventh transfer structure ZJ7. The third insulation structure may be located in one or more insulation film layers on a side of the second transparent electrode layer DJ away from the base substrate 200.

In this way, a transfer connection between the first touch line group Z1 and the first touch lead 231 may be achieved through the fourth transfer structure ZJ4. Furthermore, in the embodiments of the present disclosure, the second opening H2 is provided on the first common signal line 211 to make space for the fourth transfer structure ZJ4, so that the position of the third common signal line 213 in the lead region YX may remain unchanged.

Referring to FIG. 24A, in some specific embodiments, the first touch line 221 is connected to the fourth transfer structure ZJ4 through a fifth transfer structure ZJ5 located in the first conductive layer DD1. A size of the fifth transfer structure ZJ5 in the second direction X is substantially the same as a size of the fourth transfer structure ZJ4 in the second direction X, and an orthographic projection of the fifth transfer structure ZJ5 on the base substrate 200 falls within an orthographic projection of the second opening H2 on the base substrate 200. The display substrate includes a plurality of data lines DL, and an orthographic projection of at least one data line DL on the base substrate 200 is located between orthographic projections of two adjacent second openings H2 on the base substrate 200.

Exemplarily, the size of the fifth transfer structure ZJ5 in the second direction X is greater than a size of the fifth transfer structure ZJ5 in the first direction Y. Referring to FIG. 25A, the fifth transfer structure ZJ5 is a strip structure extending in the second direction X. Through the fifth transfer structure ZJ5, a connection area between the first touch line 221 and the fourth transfer structure ZJ4 may be increased.

In the embodiments of the present disclosure, two adjacent second openings H2 may refer to that no other second openings H2 is provided between the two second openings H2. Referring to FIG. 25A, three data lines DL are provided between two adjacent second openings H2, where a middle one of the data lines DL does not overlap with the second openings H2, and two data lines DL on left and right sides overlap partially with adjacent second openings H2 respectively. In this way, the data line DL may be located at most at the edge of the second opening H2, so as to keep a sufficient distance from the fifth transfer structure ZJ5. When the display substrate adopts the first stacked structure or the second stacked structure, the data line DL and the fifth transfer structure ZJ5 are both located in the first conductive layer DD1, and the above method may be implemented to avoid short-circuit between the data line and the fifth transfer structure.

FIG. 24C schematically shows a schematic diagram of a connection region according to an embodiment of the present disclosure.

With reference to FIG. 24A to FIG. 24C, in some specific embodiments, the display substrate further includes a display binding end PAD1 in the binding region Q2 and a data lead DLY connected between each data line DL and the display binding end PAD1. An orthographic projection of a connection region LJQ of the data line DL and the data lead DLY on the base substrate 200 defines a ninth pattern, and an orthographic projection of the seventh line segment L7 on the base substrate 200 defines a tenth pattern. The ninth pattern is located on a side of the tenth pattern away from the orthographic projection of the display region AA on the base substrate.

Optionally, the data lead DLY and the data line DL are arranged in different layers. For example, the data lead DLY and the gate line GL are arranged in the same layer. In the connection region LJQ of the data line DL and the data lead DLY, the data line DL may be connected to the corresponding data lead DLY through an eighth via hole. In the embodiments of the present disclosure, the data line DL extends into the lead region YX in the first direction Y. After being connected to the data line DL, the data lead DLY bends and extends towards the corresponding display binding end PAD1. After extending to a position of the display binding end PAD1, the data lead DLY is connected to a corresponding binding terminal on the display binding end PAD1.

With reference to FIG. 5, FIG. 6 and FIG. 24A, in some specific embodiments, the first common signal line 211 includes an eighth line segment L8 and a ninth line segment L9 in the lead region YX. The eighth line segment L8 extends from the first side region Q31 towards the touch binding end PAD2, and the ninth line segment L9 extends from the second side region Q32 towards the touch binding end PAD2. The second common signal line 212 includes a tenth line segment L10 and an eleventh line segment L11 in the lead region YX. The tenth line segment L10 extends from the first side region Q31 towards the touch binding end PAD2, and the eleventh line segment L11 extends from the second side region Q32 towards the touch binding end PAD2. An orthographic projection of the eighth line segment L8 on the base substrate 200, an orthographic projection of the ninth line segment L9 on the base substrate 200, an orthographic projection of the tenth line segment L10 on the base substrate 200 and an orthographic projection of the eleventh line segment L11 on the base substrate 200 are located on a side of the ninth pattern away from the display region AA.

With reference to FIG. 8 and FIG. 24A, the eighth line segment L8, the ninth line segment L9, the tenth line segment L10 and the eleventh line segment L11 extend in the second direction X. The eighth line segment L8, the ninth line segment L9, the tenth line segment L10 and the eleventh line segment L11 are arranged on a lower side of the connection region LJQ, so as to avoid short-circuit with the data line DL. Optionally, at least one of the eighth line segment L8, the ninth line segment L9, the tenth line segment L10 or the eleventh line segment L11 overlaps with the data lead DLY.

Optionally, the display substrate further includes a plurality of second touch leads 232. Exemplarily, each second touch line group Z2 is connected to the touch binding end PAD2 through a second touch lead 232. For example, the second touch lead 232 has one end connected to a second touch line group Z2 in the second side edge Q32, and the other end extending from the second side region Q32 to the lead region YX. After converging to a side of the touch binding end PAD2 close to the display region AA, the plurality of second touch leads 232 are connected to corresponding sensing terminals on the touch binding end PAD2. Exemplarily, in the lead region YX, the second touch lead 232 overlaps with the data lead DLY, and the second touch lead 232 is arranged in a different layer from the data lead DLY to avoid short-circuit with the data lead DLY. For example, the second touch lead 232 is arranged in the same layer as the data line DL, or the second touch lead 232 is arranged in the same layer as the second touch line 222.

In some specific embodiments, the tenth line segment L10 includes a second sub-line segment L101, a third sub-line segment L102 and a bending sub-line segment connected between the second sub-line segment L101 and the third sub-segment L102, and the second sub-line segment L101 and the third sub-line segment L102 both extend in the second direction X. At least one of the orthographic projection of the eighth line segment L8 on the base substrate 200 or the orthographic projection of the ninth line segment L9 on the base substrate 200 is located between an orthographic projection of the second sub-line segment L101 on the base substrate 200 and an orthographic projection of the third sub-segment L102 on the base substrate 200.

Exemplarily, on the display substrate, the second sub-line segment L101 extends from left to right, the third sub-line segment L102 extends from right to left, and at least one of the eighth sub-line segment L8 and the ninth line segment L9 is located between the second sub-line segment L101 and the third sub-line segment L102, so that the second sub-line segment L101, the third sub-line segment L102 and the eighth line segment L8 (or the ninth line segment L9) may be closely arranged together, which may help improve the space utilization. Optionally, the ninth line segment L9 overlaps with the bending sub-line segment, and in an overlapping region thereof, the ninth line segment L9 may achieve bridging through a transfer structure located in the second transparent electrode layer DJ.

At least some embodiments of the present disclosure further provide a display panel, which includes the display substrate as described above. The display panel has a display region AA, a peripheral region NA, and related structures therein. For example, the display panel may be a liquid crystal display panel.

At least some embodiments of the present disclosure further provide a display device. The display device may include any apparatus or product having a display function. For example, the display device may be a smart phone, a mobile phone, an e-book reader, a desktop personal computer (PC), a laptop PC, a netbook PC, a personal digital assistant (PDA), a portable multimedia player (PMP), a digital audio player, a mobile medical apparatus, a camera, a wearable apparatus (such as a head-mounted apparatus, electronic clothing, electronic bracelet, electronic necklace, electronic accessory, electronic tattoo, or smart watch), a television, etc.

It should be understood that the display device according to the embodiments of the present disclosure has all the features and advantages of the above-mentioned display substrate and display panel. The details may be referred to the above descriptions and will not be repeated here.

Those skilled in the art may understand that features described in the embodiments of the present disclosure and/or the the claims may be combined/conjoined in various ways, even if such combinations or conjunctions are not explicitly described in the present disclosure. In particular, without departing from the spirit and teachings of the present disclosure, the features described in the embodiments of the present disclosure and/or the the claims may be combined/conjoined in various ways. All these combinations and/or conjunctions fall within the scope of the present disclosure.

The embodiments of the present disclosure have been described above. However, these embodiments are for illustrative purposes only, and are not intended to limit the scope of the present disclosure. Although the embodiments have been described separately above, this does not mean that measures in each embodiment may not be used in combination advantageously. The scope of the present disclosure is defined by the appended claims and their equivalents. Those skilled in the art may make various substitutions and modifications without departing from the scope of the present disclosure, and these substitutions and modifications should all fall within the scope of the present disclosure.

1. A display substrate, comprising a display region and a peripheral region at least partially surrounding the display region, wherein the peripheral region comprises a binding region and a binding opposite region opposite to each other in a first direction and two side regions opposite to each other in a second direction intersecting with the first direction, and the display substrate further comprises:
a base substrate;
a second transparent electrode layer provided on the base substrate;
a first conductive layer and a second conductive layer provided on the base substrate, wherein the first conductive layer and the second conductive layer are located between the base substrate and the second transparent electrode layer;
a sub-pixel provided on the base substrate and located in the display region, wherein the sub-pixel comprises a second electrode in the second transparent electrode layer;
a third common signal line provided on the base substrate and located in the peripheral region; and
M first touch line groups and N second touch line groups provided on the base substrate, wherein the M first touch line groups are arranged in the second direction, the N second touch line groups are arranged in the first direction, each of the M first touch line groups comprises at least one first touch line, the first touch lines in one and the same first touch line group are connected in parallel, each of the N second touch line groups comprises at least one second touch line, the second touch lines in one and the same second touch line group are connected in parallel, the first touch lines are located in the first conductive layer, the second touch lines are located in the second conductive layer, and the first touch lines are insulated and spaced apart from the second touch lines,
wherein in an outermost first touch line group among the M first touch line groups, a part of the first touch lines is located in the display region, a second part of the first touch lines is located in at least one of the side regions, and the first touch lines and the third common signal line are arranged such that:
the first touch lines and a part of the third common signal line in at least one of the side regions are arranged in the same layer and spaced apart from each other, or
the first touch lines and the part of the third common signal line in at least one of the side regions are arranged in different layers,
where M and N are positive integers.

2. The display substrate according to claim 1, wherein the first touch lines and the part of the third common signal line in at least one of the side regions are arranged in the same layer;
wherein an orthographic projection of the part of the third common signal line in at least one of the side regions on the base substrate defines a first pattern; and
wherein in the outermost first touch line group among the M first touch line groups, an orthographic projection of the first touch lines in the display region on the base substrate defines a second pattern, an orthographic projection of the first touch lines in at least one of the side regions on the base substrate defines a third pattern, and the first pattern is located between the second pattern and the third pattern.

3. The display substrate according to claim 1, wherein in the outermost first touch line group among the M first touch line groups, the first touch lines in the display region have a first wire distance, the first touch lines in at least one of the side regions have a second wire distance, and the first wire distance is greater than or equal to the second wire distance.

4. The display substrate according to claim 3, wherein the first touch lines in the first touch line groups other than the outermost first touch line group among the M first touch line groups have a third wire distance, and the third wire distance is equal to the first wire distance.

5. The display substrate according to claim 1, wherein in the M first touch line groups, the outermost first touch line group has a same resistance as other first touch line groups.

6. The display substrate according to claim 1, wherein the first touch lines and the part of the third common signal line in at least one of the side regions are arranged in different layers;
wherein an orthographic projection of the third common signal line on the base substrate defines a first pattern; and
wherein in the outermost first touch line group among the M first touch line groups, an orthographic projection of the first touch lines in the display region on the base substrate defines a second pattern, an orthographic projection of the first touch lines in at least one of the side regions on the base substrate defines a fourth pattern, and the first pattern overlaps with the fourth pattern.

7. The display substrate according to claim 1, wherein the two side regions comprise a first side region and a second side region, the display substrate further comprises a first common signal line, a second common signal line and a touch binding end provided on the base substrate, the first common signal line and the second common signal line are located in the peripheral region, and the touch binding end is located in the binding region;
wherein the first common signal line and the second common signal line are insulated and spaced apart from each other, and the first common signal line and the second common signal line are respectively connected to the touch binding end;
wherein in the binding opposite region, an orthographic projection of the first common signal line on the base substrate is located on a side of an orthographic projection of the second common signal line on the base substrate close to an orthographic projection of the display region on the base substrate;
wherein in at least one of the side regions, the orthographic projection of the second common signal line on the base substrate is located on a side of the orthographic projection of the first common signal line on the base substrate close to the orthographic projection of the display region on the base substrate; and
wherein the first touch line group is connected to the first common signal line in the binding opposite region, and the second touch line group is connected to the second common signal line in the first side region.

8. The display substrate according to claim 7, wherein the peripheral region further comprises a plurality of corner regions, and at least one of the corner regions is located between the binding opposite region and at least one of the side regions;
wherein in at least one of the corner regions, the first common signal line comprises a first extension portion, a second extension portion and a first connecting portion connected between the first extension portion and the second extension portion, and the second common signal line comprises a third extension portion, a fourth extension portion and a second connecting portion connected between the third extension portion and the fourth extension portion; and
wherein the first extension portion and the third extension portion extend in the second direction and are arranged in the same layer, the second extension portion and the fourth extension portion extend in the first direction and are arranged in the same layer, the first connecting portion is located in the second transparent electrode layer, and the first connecting portion extends in the second direction and spans over the fourth extension portion.

9. The display substrate according to claim 7, wherein the display substrate further comprises a data line provided on the base substrate, the second common signal line comprises a first sub-line segment in the first side edge region, the first sub-line segment and the data line are arranged in the same layer, and the second touch line and the data line are arranged in different layers;
wherein an orthographic projection of a part of the second touch line group in the first side region on the base substrate overlaps with an orthographic projection of the first sub-line segment on the base substrate, and the second touch line group is connected to the first sub-line segment through a second transfer structure in an overlapping region of the part of the second touch line group and the first sub-line segment; and
wherein the second transfer structure is located in the second transparent electrode layer, second transfer structures connected to different second touch line groups are spaced apart from each other, or the second transfer structures connected to different second touch line groups are formed into an integrated structure.

10. The display substrate according to claim 7, wherein the display substrate further comprises a data line provided on the base substrate, the second common signal line comprises a first sub-line segment in the first side region, the first sub-line segment and the data line are arranged in the same layer, and the second touch line and the data line are arranged in different layers; and
wherein an orthographic projection of a part of the second touch line group in the first side region on the base substrate does not overlap with an orthographic projection of the first sub-line segment on the base substrate, and a plurality of second touch line groups are connected to the first sub-line segment through one and the same third transfer structure.

11. The display substrate according to claim 10, wherein a distance between the second touch line group and the second common signal line in the second direction is less than or equal to 3500 μm.

12. The display substrate according to claim 7, wherein the display substrate further comprises:
a data line and a gate line provided on the base substrate;
a shift register unit provided on the base substrate and located in at least one of the side regions, wherein an orthographic projection of the shift register unit on the base substrate is located on a side of the orthographic projection of the second common signal line on the base substrate away from the orthographic projection of the display region on the base substrate; and
a first signal line provided on the base substrate and connected to the shift register unit, wherein the first signal line is arranged in the same layer as at least one of the data line and the gate line, and an orthographic projection of the first signal line on the base substrate is located on a side of the orthographic projection of the shift register unit on the base substrate away from the orthographic projection of the second common signal line on the base substrate.

13. The display substrate according to claim 7, wherein the display substrate further comprises:
a data line and a gate line provided on the base substrate; and
a shift register unit provided on the base substrate and located in at least one of the side regions, wherein an orthographic projection of the shift register unit on the base substrate is located on a side of the orthographic projection of the second common signal line on the base substrate close to the orthographic projection of the display region on the base substrate; and
wherein the second touch line is arranged in a different layer from the data line and the gate line, and an orthographic projection of at least one second touch line on the base substrate overlaps with the orthographic projection of the shift register unit on the base substrate.

14. The display substrate according to claim 13, wherein an orthographic projection of the first touch line on the base substrate does not overlap with the orthographic projection of the shift register unit on the base substrate.

15. The display substrate according to claim 7, wherein the display substrate further comprises: a data line and a gate line provided on the base substrate; and a shift register unit provided on the base substrate and located in at least one of the side regions, wherein an orthographic projection of the shift register unit on the base substrate is located on a side of the orthographic projection of the second common signal line on the base substrate close to the orthographic projection of the display region on the base substrate; wherein the first touch line and the second touch line are arranged in different layers from the data line and the gate line; and wherein an orthographic projection of at least one second touch line on the base substrate overlaps with an orthographic projection of the shift register unit on the base substrate, and an orthographic projection of at least one first touch line on the base substrate overlaps with the orthographic projection of the shift register unit on the base substrate; or
wherein the display substrate comprises: a plurality of shift register units provided on the base substrate and located in at least one of the side regions, wherein an orthographic projection of the shift register units on the base substrate is located on a side of the orthographic projection of the second common signal line on the base substrate close to the orthographic projection of the display region on the base substrate; and wherein the plurality of shift register units are arranged in the first direction, a first gap is formed between two adjacent shift register units, and an orthographic projection of at least one second touch line on the base substrate passes through an orthographic projection of the first gap on the base substrate.

16. (canceled)

17. The display substrate according to claim 7, wherein an orthographic projection of the M first touch line groups on the base substrate defines a seventh pattern, and the orthographic projection of the first common signal line on the base substrate at least partially surrounds the seventh pattern; wherein an orthographic projection of the N second touch line groups on the base substrate defines an eighth pattern, and the orthographic projection of the second common signal line on the base substrate at least partially surrounds the eighth pattern; and wherein an orthographic projection of the third common signal line on the base substrate at least partially surrounds the orthographic projection of the display region on the base substrate, and either of the orthographic projection of the first common signal line on the base substrate and the orthographic projection of the second common signal line on the base substrate is located on a side of the orthographic projection of the third common signal line on the base substrate away from the orthographic projection of the display region on the base substrate; or
wherein an orthographic projection of the M first touch line groups on the base substrate defines a seventh pattern, and the orthographic projection of the first common signal line on the base substrate at least partially surrounds the seventh pattern; wherein an orthographic projection of the N second touch line groups on the base substrate defines an eighth pattern, and the orthographic projection of the second common signal line on the base substrate at least partially surrounds the eighth pattern; and wherein an orthographic projection of the third common signal line on the base substrate at least partially surrounds the orthographic projection of the display region on the base substrate, and either of the orthographic projection of the first common signal line on the base substrate and the orthographic projection of the second common signal line on the base substrate is located on a side of the orthographic projection of the third common signal line on the base substrate close to the orthographic projection of the display region on the base substrate.

18. (canceled)

19. The display substrate according to claim 7, wherein an orthographic projection of the M first touch line groups on the base substrate defines a seventh pattern, and the orthographic projection of the first common signal line on the base substrate at least partially surrounds the seventh pattern; wherein an orthographic projection of the N second touch line groups on the base substrate defines an eighth pattern, and the orthographic projection of the second common signal line on the base substrate at least partially surrounds the eighth pattern; wherein an orthographic projection of the third common signal line on the base substrate at least partially surrounds the orthographic projection of the display region on the base substrate; wherein in at least one of the binding region and the binding opposite region, either of the orthographic projection of the first common signal line on the base substrate and the orthographic projection of the second common signal line on the base substrate is located on a side of the orthographic projection of the third common signal line on the base substrate away from the orthographic projection of the display region on the base substrate; and wherein in at least one of the side regions, either of the orthographic projection of the first common signal line on the base substrate and the orthographic projection of the second common signal line on the base substrate is located on a side of the orthographic projection of the third common signal line on the base substrate close to the orthographic projection of the display region on the base substrate; or
wherein an orthographic projection of the M first touch line groups on the base substrate defines a seventh pattern, and the orthographic projection of the first common signal line on the base substrate at least partially surrounds the seventh pattern; wherein an orthographic projection of the N second touch line groups on the base substrate defines an eighth pattern, and the orthographic projection of the second common signal line on the base substrate at least partially surrounds the eighth pattern; wherein an orthographic projection of the third common signal line on the base substrate at least partially surrounds the orthographic projection of the display region on the base substrate; wherein in at least one of the binding region and the binding opposite region, either of the orthographic projection of the first common signal line on the base substrate and the orthographic projection of the second common signal line on the base substrate is located on a side of the orthographic projection of the third common signal line on the base substrate close to the orthographic projection of the display region on the base substrate; and wherein in at least one of the side regions, either of the orthographic projection of the first common signal line on the base substrate and the orthographic projection of the second common signal line on the base substrate is located on a side of the orthographic projection of the third common signal line on the base substrate away from the orthographic projection of the display region on the base substrate.

20. (canceled)

21. The display substrate according to claim 7, wherein the display substrate further comprises: a gate line provided on the base substrate; and a common electrode line provided on the base substrate and located in the display region, wherein the common electrode line is connected to the second electrode in the sub-pixel; wherein the third common signal line comprises a fifth line segment in the binding opposite region, the fifth line segment is connected to the common electrode line through a sixth transfer structure located in the second transparent electrode layer; wherein the first common signal line comprises a first line segment in the binding opposite region, the first line segment and the gate line are arranged in the same layer, and the first touch line and the gate line are arranged in different layers; and wherein a first opening is provided on the sixth transfer structure, an orthographic projection of a part of the first touch line group in the binding opposite region on the base substrate overlaps with an orthographic projection of the first line segment on the base substrate, the first touch line group is connected to the first line segment through a first transfer structure in an overlapping region of the first touch line group and the first line segment, the first transfer structure is located in the second transparent electrode layer, and an orthographic projection of the first transfer structure on the base substrate falls within an orthographic projection of the first opening on the base substrate; or
wherein the display substrate further comprises: a data line and a gate line provided on the base substrate; wherein the first common signal line comprises a first line segment in the binding opposite region, the first line segment and the first touch line are arranged in the same layer, and the first line segment is arranged in a different layer from the data line and the gate line; and wherein in the binding opposite region, the first touch line group is directly connected to the first line segment.

22. (canceled)

23. The display substrate according to claim 7, wherein the peripheral region further comprises a lead region between the display region and the binding region, and the display substrate further comprises a data line, a second common display signal line and a first touch lead provided on the base substrate; wherein the third common signal line comprises a seventh line segment in the lead region, an extension direction of the seventh line segment is substantially the same as an extension direction of the second common display signal line, an orthographic projection of the seventh line segment on the base substrate is located on a side of an orthographic projection of the second common display signal line on the base substrate close to the display region, and the seventh line segment is connected to the second common display signal line through a seventh transfer structure located in the second transparent electrode layer; wherein in the lead region, the first touch line is connected to the touch binding end through a first touch lead, the first touch line and the data line are arranged in the same layer, and the first touch lead is arranged in a different layer from the data line;
wherein a second opening is provided on the seventh transfer structure, the first touch line is connected to the first touch lead through a fourth transfer structure located in the second transparent electrode layer, and an orthographic projection of the fourth transfer structure on the base substrate falls within an orthographic projection of the second opening on the base substrate;
wherein the display substrate comprises a plurality of data lines, and an orthographic projection of at least one of the plurality of data lines on the base substrate is located between orthographic projections of two adjacent second openings on the base substrate;
wherein the display substrate further comprises a display binding end in the binding region and a data lead connected between each of the plurality of data lines and the display binding end;
wherein an orthographic projection of a connecting region of the data line and the data lead on the base substrate defines a ninth pattern, and an orthographic projection of the seventh line segment on the base substrate defines a tenth pattern;
wherein the ninth pattern is located on a side of the tenth pattern away from the orthographic projection of the display region on the base substrate;
wherein the first common signal line comprises an eighth line segment and a ninth line segment in the lead region, the eighth line segment extends from the first side region toward the touch binding end, and the ninth line segment extends from the second side region toward the touch binding end;
wherein the second common signal line comprises a tenth line segment and an eleventh line segment in the lead region, the tenth line segment extends from the first side region toward the touch binding end, and the eleventh line segment extends from the second side region toward the touch binding end;
wherein an orthographic projection of the eighth line segment on the base substrate, an orthographic projection of the ninth line segment on the base substrate, an orthographic projection of the tenth line segment on the base substrate and an orthographic projection of the eleventh line segment on the base substrate are located on a side of the ninth pattern away from the display region;
wherein the tenth line segment comprises a second sub-line segment, a third sub-line segment and a bending sub-line segment connected between the second sub-line segment and the third sub-line segment, and the second sub-line segment and the third sub-line segment extend in the second direction; and
wherein either of the orthographic projection of the eighth line segment on the base substrate and the orthographic projection of the ninth line segment on the base substrate is located between an orthographic projection of the second sub-line segment on the base substrate and an orthographic projection of the third sub-line segment on the base substrate.

24-27. (canceled)

28. A display device, comprising the display substrate according to claim 1.
